(19) United States
(12) Patent Application Publication
(10) Pub. No.: US 2026/0223713 A1
(43) Pub. Date: Jul. 30, 2026

(54) ASSEMBLY STRUCTURE AND MANUFACTURING METHOD FOR MANUFACTURING THE SAME

(71) Applicant: Advanced Semiconductor Engineering, Inc., Kaohsiung (TW)

(72) Inventors: Chih-Jing HSU, Kaohsiung (TW); Yu-Yuan YEH, Kaohsiung (TW); Zhao-Ze JIANG, Kaohsiung (TW); Hsu-Nan FANG, Kaohsiung (TW); Chen-Hung LEE, Kaohsiung (TW); Che-Ming HSU, Kaohsiung (TW); Min-Tzu HSU, Kaohsiung (TW)

(73) Assignee: Advanced Semiconductor Engineering, Inc., Kaohsiung (TW)

(21) Appl. No.: 19/294,231

(22) Filed: Aug. 7, 2025

Related U.S. Application Data
(60) Provisional application No. 63/749,463, filed on Jan. 24, 2025.

(51) Int. Cl. H01L 23/00

(52) U.S. Cl. CPC H10W 72/072; H10W 72/20; H10W 72/30; H10W 72/851; H10W 72/07236; H10W 72/234; H10W 74/15; H10W 80/327; H10W 90/722; H10W 90/732

(57) ABSTRACT

An assembly structure includes a first electronic device, a second electronic device, a conductive portion and a dielectric structure. The second electronic device is disposed over the first electronic device. The conductive portion connects the first electronic device and the second electronic device. The dielectric structure encapsulates the conductive portion, and extends beyond a lateral surface of the first electronic device and a lateral surface of the second electronic device.

### CROSS REFERENCE TO RELATED APPLICATION

This application claims the benefit of U.S. Provisional Application No. 63/749,463, filed Jan. 24, 2025, the content of which is incorporated herein by reference in its entirety.

### BACKGROUND

### 1. Field of the Disclosure

The present disclosure relates to an assembly structure and a manufacturing method for manufacturing the same, and to an assembly structure including a dielectric structure and a manufacturing method for manufacturing the same.

### 2. Description of the Related Art

In an existing semiconductor electronic package structure, a plurality of electronic devices may be stacked on one another. Due to the numerous high-temperature thermal cycles involved in the manufacturing process, significant warpage of the electronic devices and solder cracking between the electronic devices can occur in the semiconductor package. As a result, both the manufacturing yield and the long-term reliability of the semiconductor electronic package may be adversely affected.

### SUMMARY

In some embodiments, an assembly structure includes a first electronic device, a second electronic device, a conductive portion and a dielectric structure. The second electronic device is disposed over the first electronic device. The conductive portion connects the first electronic device and the second electronic device. The dielectric structure encapsulates the conductive portion, and extends beyond a lateral surface of the first electronic device and a lateral surface of the second electronic device.

In some embodiments, a manufacturing method includes: forming a first dielectric layer on a first electronic device to cover an end surface of a first reflowable material on the first electronic device, wherein the first dielectric layer includes an organic material; removing a portion of the first dielectric layer to expose the first reflowable material; forming a second dielectric layer on a second electronic device to cover an end surface of a second reflowable material on the second electronic device, wherein the second dielectric layer includes an organic material; removing a portion of the second dielectric layer to expose the second reflowable material; bonding the first dielectric layer and the second dielectric layer together to collectively form a dielectric structure; and fusing the first reflowable material and the second reflowable material together to collectively form a solder structure.

In some embodiments, a manufacturing method includes: providing a first electronic device including a first pad embedded in and exposed by a first conductive structure of the first electronic device, wherein the first conductive structure includes an inorganic material; forming a second dielectric layer on a second electronic device, wherein the second dielectric layer exposes a second reflowable material, and includes an organic material; bonding the first conductive structure and the second dielectric layer; and bonding the first pad and the second reflowable material.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an assembly structure according to some embodiments of the present disclosure.

FIG. 2 illustrates a cross-sectional view of an assembly structure according to some embodiments of the present disclosure.

FIG. 3 through FIG. 11 illustrate a manufacturing method for manufacturing an assembly structure according to some embodiments of the present disclosure.

FIG. 12 illustrates a cross-sectional view of an assembly structure according to some embodiments of the present disclosure.

FIG. 13 illustrates an enlarged view of an area “A” of FIG. 12.

FIG. 14 through FIG. 31 illustrate a manufacturing method for manufacturing an assembly structure according to some embodiments of the present disclosure.

FIG. 32 illustrates a cross-sectional view of an assembly structure according to some embodiments of the present disclosure.

FIG. 33 illustrates a cross-sectional view of an assembly structure according to some embodiments of the present disclosure.

FIG. 34 illustrates an enlarged view of an area “B” of FIG. 33.

FIG. 35 through FIG. 49 illustrate a manufacturing method for manufacturing an assembly structure according to some embodiments of the present disclosure.

FIG. 50 illustrates a cross-sectional view of an assembly structure according to some embodiments of the present disclosure.

FIG. 51 illustrates a cross-sectional view of an assembly structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

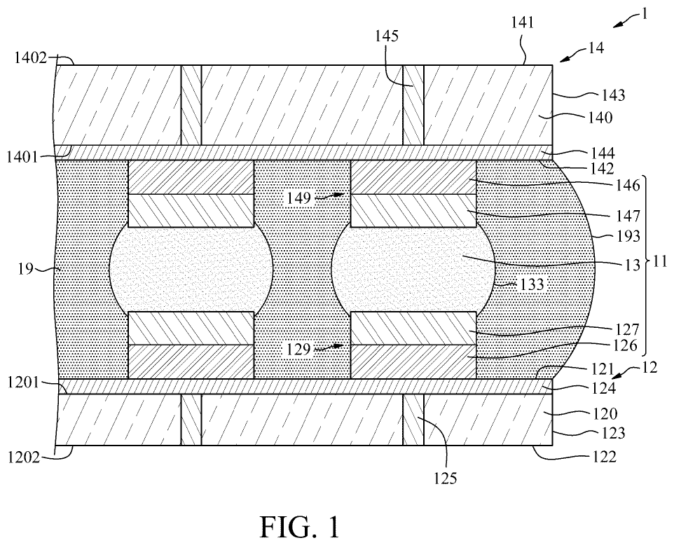

FIG. 1 illustrates a cross-sectional view of an assembly structure 1 according to some embodiments of the present disclosure. The assembly structure 1 may be an electronic package structure, a semiconductor package structure, an electronic structure, an electronic device, a semiconductor device or a three-dimensional form factor device. The assembly structure 1 may include a first electronic device 12, a second electronic device 14, at least one conductive portion 11 and a dielectric structure 19. The assembly structure 1 may be used in a voltage regulator. The voltage regulator may include a control logic and a redundant control logic, and may perform a step of engaging the redundant control logic and disengaging the control logic.

The first electronic device 12 may be a substrate, a semiconductor die, a semiconductor chip or an integrated circuit die. In some embodiments, the first electronic device 12 may be a logic device such as a logic die or a logic chip. In some embodiments, the first electronic device 12 may include an application-specific integrated circuit (ASIC) chip. Alternatively, the first electronic device 12 may include a memory device such as a high bandwidth memory (HBM).

The first electronic device 12 may have a top surface 121 (e.g., an upper surface, a first surface or a first outer surface), a bottom surface 122 (e.g., a lower surface, a second surface or a second outer surface) opposite to the top surface 121, and a lateral surface 123 extending between the top surface 121 and the bottom surface 122. The first electronic device 12 may include a main portion 120, a conductive structure 124 and a plurality of through vias 125.

The main portion 120 may be a semiconductor substrate, and may include, for example, silicon (Si) or other semiconductor materials. The main portion 120 may have a top surface 1201 (e.g., an active surface) and a bottom surface 1202 (e.g., a backside surface) opposite to the top surface 1201. The bottom surface 1202 of the main portion 120 may be the bottom surface 122 of the first electronic device 12. The through vias 125 may extend through the main portion 120, and may be also referred to as “through silicon vias (TSVs)”. The through vias 125 may be formed outside a stress concentration region in the main portion 120.

The conductive structure 124 may be disposed on the top surface 1201 of the main portion 120. The conductive structure 124 may be also referred to as “an outer structure”, “an addition structure”, “a stacked structure”, or “a built-up structure”. A top surface of the conductive structure 124 may be the top surface 121 of the first electronic device 12. In some embodiments, the conductive structure 124 may include a plurality of front-end-of-line (FEOL) devices, such as resistors, capacitors, inductors, and/or transistors. In some embodiments, the conductive structure 124 may further include at least one back-end-of-line (BEOL) interconnect pattern, e.g., a plurality of patterned circuit layers, electrically connected to the front-end-of-line (FEOL) devices. The conductive structure 124 may include a dielectric structure, a plurality of circuit layers (including a plurality traces and a plurality of pads) embedded in the dielectric structure, and a plurality of inner vias. The dielectric structure may be a multi-layer film stack deposited on the main portion 120. The inner vias may be disposed in the dielectric structure, and may connect the circuit layers. The circuit layers of the conductive structure 124 may be electrically connected to the through vias 125. The dielectric structure of the conductive structure 124 may include inorganic material or organic material.

The second electronic device 14 may be disposed over the first electronic device 12. The second electronic device 14 may be a substrate, a semiconductor die, a semiconductor chip or an integrated circuit die. In some embodiments, the second electronic device 14 may be a logic device such as a logic die or a logic chip. In some embodiments, the second electronic device 14 may include an application-specific integrated circuit (ASIC) chip. Alternatively, the second electronic device 14 may include a memory device such as a high bandwidth memory (HBM).

The second electronic device 14 may have a top surface 141 (e.g., an upper surface, a first surface or a first outer surface), a bottom surface 142 (e.g., a lower surface, a second surface or a second outer surface) opposite to the top surface 141, and a lateral surface 143 extending between the top surface 141 and the bottom surface 142. The bottom surface 142 of the second electronic device 14 may have a general trend substantially parallel to the top surface 121 of the first electronic device 12. The second electronic device 14 may include a main portion 140, a conductive structure 144 and a plurality of through vias 145.

The main portion 140 may be a semiconductor substrate, and may include, for example, silicon (Si) or other semiconductor materials. The main portion 140 may have a bottom surface 1401 (e.g., an active surface) and a top surface 1402 (e.g., a backside surface) opposite to the bottom surface 1401. The top surface 1402 of the main portion 140 may be the top surface 141 of the second electronic device 14. The through vias 145 may extend through the main portion 140, and may be also referred to as “through silicon vias (TSVs)”.

The conductive structure 144 may be disposed on the bottom surface 1401 of the main portion 140. A bottom surface of the conductive structure 144 may be the bottom surface 142 of the second electronic device 14. In some embodiments, the conductive structure 144 may include a plurality of front-end-of-line (FEOL) devices, such as resistors, capacitors, inductors, and/or transistors. In some embodiments, the conductive structure 144 may further include at least one back-end-of-line (BEOL) interconnect pattern, e.g., a plurality of patterned circuit layers, electrically connected to the front-end-of-line (FEOL) devices. The conductive structure 144 may include a dielectric structure, a plurality of circuit layers (including a plurality traces and a plurality of pads) embedded in the dielectric structure, and a plurality of inner vias. The dielectric structure may be a multi-layer film stack deposited on the main portion 140. The inner vias may be disposed in the dielectric structure, and may connect the circuit layers. The circuit layers of the conductive structure 144 may be electrically connected to the through vias 145. The dielectric structure of the conductive structure 144 may include inorganic material or organic material.

The at least one conductive portion 11 may include a plurality of conductive portions 11 spaced apart from each other. The conductive portions 11 may be disposed between and may connect the first electronic device 12 and the second electronic device 14. The conductive portion 11 may include a first connector 129, a second connector 149 and a solder structure 13. The conductive portion 11 may be a joint structure, a metal portion or a pillar structure. The first connector 129 may extend beyond the top surface 121 of the first electronic device 12. The first connector 129 may include a first bump 126 and a first barrier layer 127. The first bump 126 may be disposed on the conductive structure 124, and may include copper (Cu). The first bump 126 may generally inhibit Van der Waals force stiction associated with the proof mass. The first barrier layer 127 may be disposed on the first bump 126, and may include nickel (Ni). The first barrier layer 127 may be transition element conformal with the first bump 126.

The second connector 149 may extend beyond the bottom surface 142 of the second electronic device 14. The second connector 149 may include a second bump 146 and a second barrier layer 147. The second bump 146 may be disposed on the conductive structure 144, and may include copper (Cu). The second barrier layer 147 may be disposed on the second bump 146, and may include nickel (Ni). The solder structure 13 may be disposed between and contact the first barrier layer 127 of the first connector 129 and the second barrier layer 147 of the second connector 149. For example, an end surface of the first barrier layer 127 and an end surface of the second barrier layer 147 may be a solder region. The solder structure 13 may include or may be formed from a solder material or a reflowable material such as Sn/Ag alloy. A lateral surface 133 of the solder structure 13 may be a convex surface. The solder structure 13 may be a single layer or a monolithic structure that is full of intermetallic compound (IMC). The solder structure 13 may be a full IMC structure with a single IMC or multiple IMCs. A portion of the solder structure 13 may contact a lateral surface of the first barrier layer 127 of the first connector 129 and a lateral surface of the second barrier layer 147 of the second connector 149. The solder structure 13 may be a self-aligned structure.

The dielectric structure 19 may encapsulate the conductive portions 11, and may fill the spaces between the conductive portions 11. The dielectric structure 19 may include or may be formed from an organic material such as polyimide (PI), benzocyclobutene (BCB) or polybenzoxazoles (PBO). The dielectric structure 19 may not include fillers. The dielectric structure 19 may be disposed between and may contact the conductive structure 124 of the first electronic device 12 and the conductive structure 144 of the second electronic device 14. The bottom surface of the dielectric structure 19 may contact the conductive structure 124 of the first electronic device 12. The top surface of the dielectric structure 19 may contact the conductive structure 144 of the second electronic device 14. The dielectric structure 19 may cover and contact the first connector 129 (e.g., the first bump 126 and the first barrier layer 127), the second connector 149 (e.g., the second bump 146 and the second barrier layer 147) and the solder structure 13. The dielectric structure 19 may be a continuous interior stress relief structure. The dielectric structure 19 may be used as a retainer. The dielectric structure 19 may have a loss tangent lower than about 0.01. A ductility of a material of the first connector 129 and the second connector 149 may be greater than a ductility of a material of the dielectric structure 19. The dielectric structure 19 may be a strain layer configured to reduce the thermal stress of the assembly structure 1 during the thermal cycle.

The dielectric structure 19 may extend beyond the lateral surface 123 of the first electronic device 12 and the lateral surface 143 of the second electronic device 14. A lateral surface 193 of the dielectric structure 19 may be a convex surface. A curvature of the lateral surface 133 of the solder structure 13 may be the same as or may be different from a curvature of the lateral surface 193 of the dielectric structure 19. The dielectric structure 19 may be a single layer or a monolithic structure that is full of cured organic material. The dielectric structure 19 may not have a horizontal interface therein. In some embodiments, the dielectric structure 19 may have a glass transition temperature (Tg) in a range from 150° C. to 250° C. The dielectric structure 19 may have a mohs hardness ranging from about 2.0 to about 4.0, such as 3.0. The dielectric structure 19 may have a Young's modulus ranging from about 1.5 GPa to about 2.0 GPa, such as 1.8 GPa.

In comparison, the dielectric structure 19 is different from the conventional molding compound (or underfill). The conventional molding compound may include epoxy with silica fillers. The conventional molding compound may have a glass transition temperature (Tg) in a range from 95° C. to 115° C. The conventional molding compound may have a Young's modulus ranging from about 7.0 GPa to 18.0 GPa.

In comparison, the dielectric structure 19 is different from the conventional inorganic bonding material such as SiO2, SiCN and SiN. For example, SiO₂ may have a Young's modulus of 73 GPa, and have a mohs hardness of 7.0. SiCN may have a Young's modulus ranging from 190 GPa to 300 GPa, and have a mohs hardness of 9.0. SiN may have a Young's modulus of 290 GPa, and have a mohs hardness of 7.0.

In comparison, the dielectric structure 19 is different from the dielectric structures of the conductive structures 124, 144. For example, the dielectric structures of the conductive structures 124, 144 may have a Young's modulus greater than 2.2 GPa. In addition, the dielectric structures of the conductive structures 124, 144 are not used for bonding. A Young's modulus ratio of the dielectric structure 19 to that of the dielectric structures of the conductive structures 124, 144 may be 0.68 to 0.81.

During manufacturing process, the dielectric structure 19 may be formed at a low temperature such as a temperature of not greater than 150° C. Thus, a warpage of the first electronic device 12 and the second electronic device 14 may be reduced. For example, the warpage of the first electronic device 12 and the second electronic device 14 may be less than 10 μm. In addition, there would not be too much IMC formed in the solder structure 13. Thus, the solder structure 13 is protected against cracking. The yield rate of the assembly structure 1 may be improved. The first electronic device 12 may be bonded to the second electronic device 14 securely through the collaborative operation of the dielectric structure 19 and the solder structure 13.

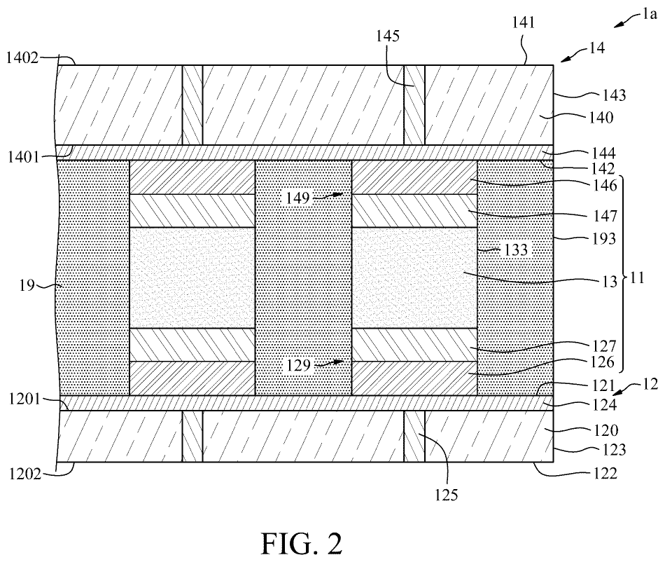

FIG. 2 illustrates a cross-sectional view of an assembly structure 1a according to some embodiments of the present disclosure. The assembly structure 1a of FIG. 2 is similar to the assembly structure 1 of FIG. 1 except for the lateral surface 133 of the solder structure 13 and the lateral surface 193 of the dielectric structure 19. The lateral surface 133 of the solder structure 13 of the assembly structure 1a of FIG. 2 may be a substantially flat surface, and may be substantially aligned with the lateral surface of the first connector 129 and the lateral surface of the second connector 149. The lateral surface 193 of the dielectric structure 19 of the assembly structure 1a of FIG. 2 may be a substantially flat surface, and may be substantially aligned with the lateral surface 123 of the first electronic device 12 and the lateral surface 143 of the second electronic device 14. In some embodiments, the lateral surface 193 of the dielectric structure 19 of the assembly structure 1a of FIG. 2 may be a convex surface. The curvature of the lateral surface 133 of the solder structure 13 may be different from the curvature of the lateral surface 193 of the dielectric structure 19.

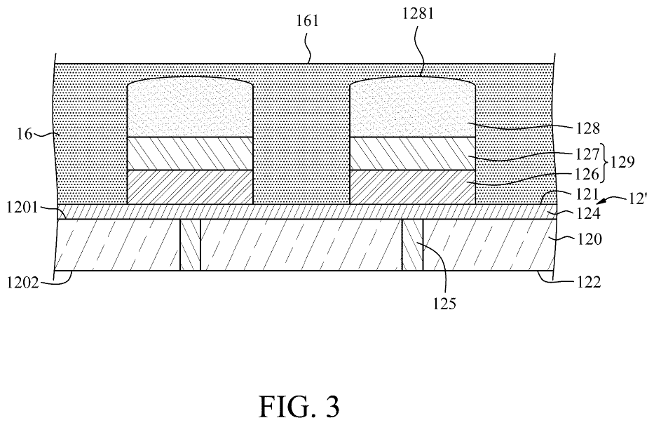

FIG. 3 through FIG. 11 illustrate a manufacturing method for manufacturing an assembly structure according to some embodiments of the present disclosure. In some embodiments, the method is for manufacturing the assembly structure 1 shown in FIG. 1.

Referring to FIG. 3, a first electronic device 12′ may be provided. The first electronic device 12′ may be similar to the first electronic device 12 of FIG. 1. The first electronic device 12′ may be a substrate or a semiconductor structure. In some embodiments, the first electronic device 12′ may be in a panel type (or a panel structure) or a wafer type (or a wafer structure).

The first electronic device 12′ may have a top surface 121 and a bottom surface 122. The first electronic device 12′ may include a main portion 120, a conductive structure 124 and a plurality of through vias 125. The main portion 120 may have a top surface 1201 and a bottom surface 1202. The through vias 125 may extend through the main portion 120. The conductive structure 124 may be disposed on the top surface 1201 of the main portion 120. In some embodiments, the conductive structure 124 of FIG. 3 may be the same as the conductive structure 124 of FIG. 1.

Then, a first bump 126 may be formed or disposed on, and may contact, the conductive structure 124 of the first electronic device 12′ by plating. The first bump 126 may be formed or disposed on the top surface 121 of the first electronic device 12′ . The first bump 126 may include copper (Cu). Then, a first barrier layer 127 may be formed or disposed on the first bump 126 by plating. The first barrier layer 127 may include nickel (Ni). The first bump 126 and the first barrier layer 127 may collectively form a first connector 129. Then, a first reflowable material 128 may be formed or disposed on the first barrier layer 127 on the first bump 126. The first reflowable material 128 may include a solder material such as Sn/Ag alloy.

Then, a first dielectric layer 16 may be formed or disposed on the top surface 121 of the first electronic device 12′ to cover the first connector 129 (e.g., the first bump 126 and the first barrier layer 127) and the top surface 1281 (e.g., an end surface) of the first reflowable material 128 on the first electronic device 12′ by coating. The amount of the first dielectric layer 16 may be determined by a plurality of threshold levels corresponding to a plurality of measured widths of the first reflowable materials 128. The first dielectric layer 16 may include an organic material such as polyimide (PI), benzocyclobutene (BCB) or polybenzoxazoles (PBO). The first dielectric layer 16 may not include fillers. The top surface 161 (e.g., an outer surface) of the first dielectric layer 16 may be higher than the top surface 1281 (e.g., the end surface) of the first reflowable material 128. Then, the first dielectric layer 16 may be pre-cured, for example, at a temperature of 140° C. for 30 minutes, so that the first dielectric layer 16 is in a B-stage state.

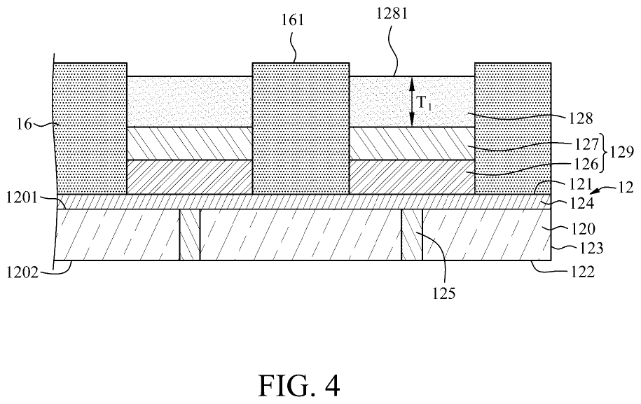

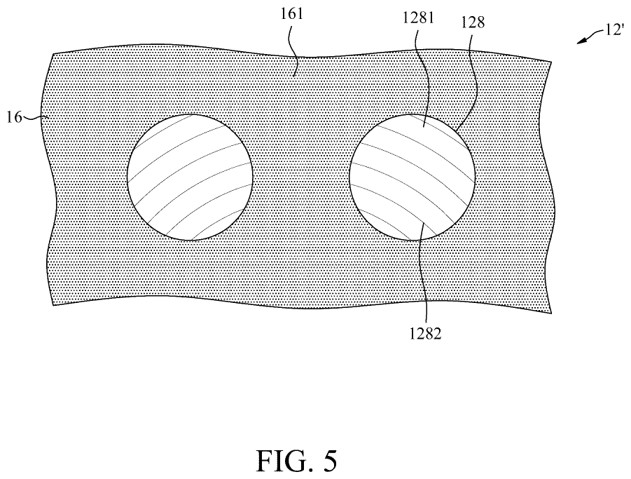

Referring to FIG. 4 and FIG. 5, wherein FIG. 5 illustrates a top view of FIG. 4, a fly-cutting process may be conducted on the top surface 161 of the first dielectric layer 16. Thus, an upper portion of the first dielectric layer 16 and an upper portion of the first reflowable material 128 may be removed concurrently by a diamond bit. After the fly-cutting process, the first dielectric layer 16 may expose the first reflowable material 128. That is, the top surface 1281 (e.g., the end surface) of the first reflowable material 128 may be exposed by the top surface 161 (e.g., the outer surface) of the first dielectric layer 16. In some embodiments, the top surface 1281 (e.g., the end surface) of the first reflowable material 128 may be substantially aligned with the top surface 161 (e.g., the outer surface) of the first dielectric layer 16. A total thickness variation (TTV) of the top surface 1281 (e.g., the end surface) of the first reflowable material 128 and the top surface 161 (e.g., the outer surface) of the first dielectric layer 16 may be less than 1 μm. In some embodiments, a removal rate of the first reflowable material 128 is higher than a removal rate of the first dielectric layer 16. Thus, the top surface 1281 (e.g., the end surface) of the first reflowable material 128 may be dished. For example, the top surface 1281 (e.g., the end surface) of the first reflowable material 128 may be recessed from the top surface 161 (e.g., the outer surface) of the first dielectric layer 16 by about 100 nm. In some embodiments, the recess between the top surface 1281 (e.g., the end surface) of the first reflowable material 128 and the top surface 161 (e.g., the outer surface) of the first dielectric layer 16 may be a trench recess.

Referring to FIG. 5, after the fly-cutting process, the top surface 1281 (e.g., the end surface) of the first reflowable material 128 may have a plurality of machining marks 1282, and may have wavy profiles. The machining marks 1282 may be curved lines spaced apart from each other. The machining marks 1282 may have equal curvatures. The first reflowable material 128 may have a first thickness T₁.

Referring to FIG. 4, then, a singulation process may be conducted so as to form a plurality of first electronic devices 12. In some embodiments, the singulation process may be not conducted yet.

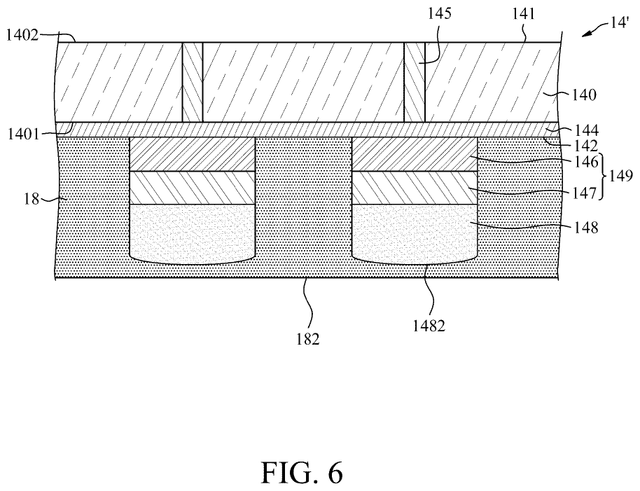

Referring to FIG. 6, a second electronic device 14′ may be provided. The second electronic device 14′ may be similar to the second electronic device 14 of FIG. 1. The second electronic device 14′ may be a substrate or a semiconductor structure. In some embodiments, the second electronic device 14′ may be in a panel type (or a panel structure) or a wafer type (or a wafer structure).

The second electronic device 14′ may have a top surface 141 and a bottom surface 142. The second electronic device 14′ may include a main portion 140, a conductive structure 144 and a plurality of through vias 145. The main portion 140 may have a top surface 1402 and a bottom surface 1401. The through vias 145 may extend through the main portion 140. The conductive structure 144 may be disposed on the bottom surface 1401 of the main portion 140. In some embodiments, the conductive structure 144 of FIG. 6 may be the same as the conductive structure 144 of FIG. 1.

Then, a second bump 146 may be formed or disposed on, and may contact, the conductive structure 144 of the second electronic device 14′ by plating. The second bump 146 may be formed or disposed on the bottom surface 142 of the second electronic device 14′ . The second bump 146 may include copper (Cu). Then, a second barrier layer 147 may be formed or disposed on the second bump 146 by plating. The second barrier layer 147 may include nickel (Ni). The second bump 146 and the second barrier layer 147 may collectively form a second connector 149. Then, a second reflowable material 148 may be formed or disposed on the second barrier layer 147 on the second bump 146. The second reflowable material 148 may include a solder material such as Sn/Ag alloy.

Then, a second dielectric layer 18 may be formed or disposed on the bottom surface 142 of the second electronic device 14′ to cover the second connector 149 (e.g., the second bump 146 and the second barrier layer 147) and the bottom surface 1482 (e.g., an end surface) of the second reflowable material 148 on the second electronic device 14′ by coating. The second dielectric layer 18 may include an organic material such as polyimide (PI), benzocyclobutene (BCB) or polybenzoxazoles (PBO). The second dielectric layer 18 may not include fillers. The bottom surface 182 (e.g., an outer surface) of the second dielectric layer 18 may be lower than the bottom surface 1482 (e.g., the end surface) of the second reflowable material 148. Then, the second dielectric layer 18 may be pre-cured, for example, at a temperature of 140° C. for 30 minutes, so that the second dielectric layer 18 is in a B-stage state.

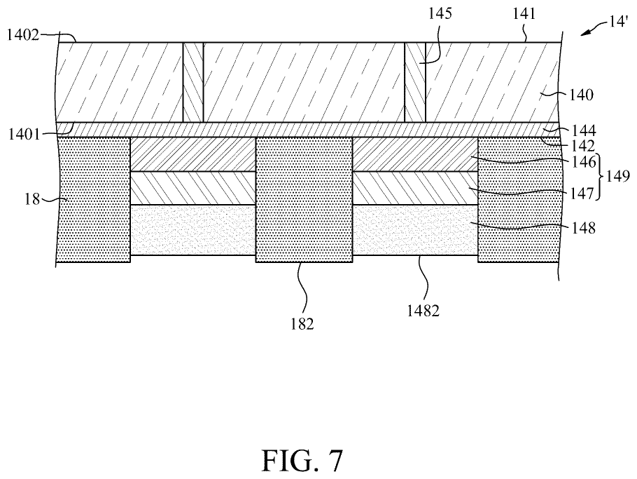

Referring to FIG. 7, a fly-cutting process may be conducted on the bottom surface 182 of the second dielectric layer 18. Thus, a lower portion of the second dielectric layer 18 and a lower portion of the second reflowable material 148 may be removed concurrently by a diamond bit. After the fly-cutting process, the second dielectric layer 18 may expose the second reflowable material 148. That is, the bottom surface 1482 (e.g., the end surface) of the second reflowable material 148 may be exposed by the bottom surface 182 (e.g., the outer surface) of the second dielectric layer 18. In some embodiments, the bottom surface 1482 (e.g., the end surface) of the second reflowable material 148 may be substantially aligned with the bottom surface 182 (e.g., the outer surface) of the second dielectric layer 18. A total thickness variation (TTV) of the bottom surface 1482 (e.g., the end surface) of the second reflowable material 148 and the bottom surface 182 (e.g., the outer surface) of the second dielectric layer 18 may be less than 1 μm. In some embodiments, the bottom surface 1482 (e.g., the end surface) of the second reflowable material 148 may be dished. For example, the bottom surface 1482 (e.g., the end surface) of the second reflowable material 148 may be recessed from the bottom surface 182 (e.g., the outer surface) of the second dielectric layer 18 by about 100 nm.

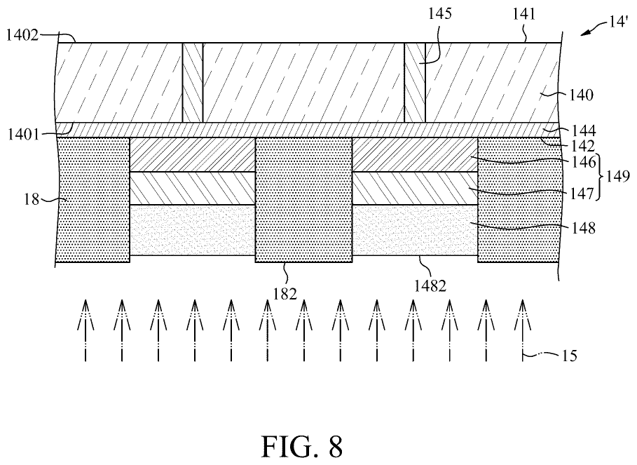

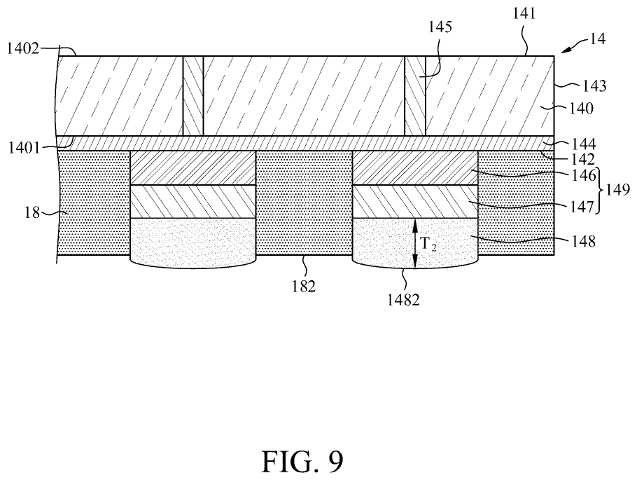

Referring to FIG. 8 and FIG. 9, the second dielectric layer 18 may be etched or thinned by descumming so that the second reflowable material 148 may protrude from the bottom surface 182 (e.g., the outer surface) of the second dielectric layer 18. In some embodiments, a descum gas 15 (including argon (Ar) and oxygen (O₂)) may be applied or supplied to the bottom surface 182 (e.g., the outer surface) of the second dielectric layer 18 to only remove a portion of the second dielectric layer 18. The bottom surface 1482 (e.g., the end surface) of the second reflowable material 148 may protrude from the bottom surface 182 (e.g., the outer surface) of the second dielectric layer 18 by less than 1 μm. The second reflowable material 148 may extend beyond the bottom surface 182 (e.g., the outer surface) of the second dielectric layer 18 by less than 1 μm. The second reflowable material 148 may have a second thickness T₂. The second thickness T₂ of the second reflowable material 148 may be substantially equal to the first thickness T₁ of the first reflowable material 128. Alternatively, the second thickness T₂ of the second reflowable material 148 may be less than or greater than the first thickness T₁ of the first reflowable material 128.

Then, a singulation process may be conducted so as to form a plurality of second electronic devices 14. In some embodiments, the singulation process may be not conducted yet.

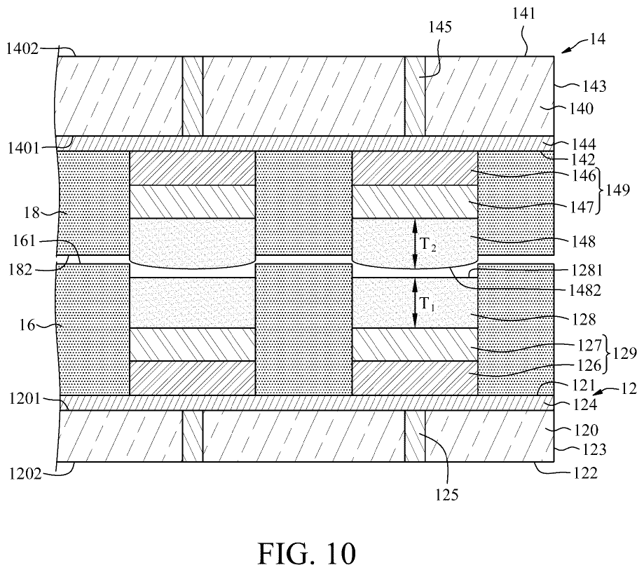

Referring to FIG. 10, the structure of FIG. 4 and the structure of FIG. 9 may be placed in a reducing atmosphere such as formic acid atmosphere, so as to remove the oxide layer on the bottom surface 1482 (e.g., the end surface) of the second reflowable material 148 and the oxide layer on the top surface 1281 (e.g., an end surface) of the first reflowable material 128. The formic acid is systematically named methanoic acid, and is the simplest carboxylic acid, and has the chemical formula HCOOH and structure H—C(═O)—O—H.

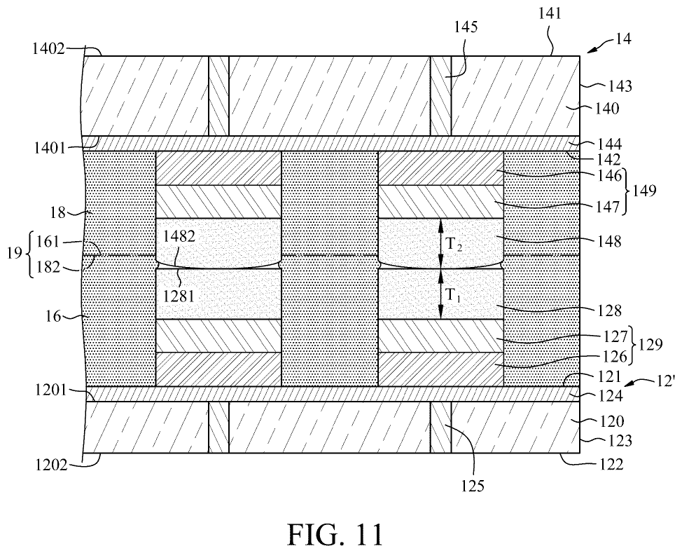

Referring to FIG. 11, the second electronic device 14 and the first electronic device 12 may move toward each other. Thus, the second reflowable material 148 may contact the first reflowable material 128. The second dielectric layer 18 may contact the first dielectric layer 16. Then, a tack bonding may be performed between the second dielectric layer 18 and the first dielectric layer 16 in the reducing atmosphere at a temperature of between 130° C. and 170° C. (e.g., at 150° C.) . Such temperature may be the glass transition temperature (Tg) of the second dielectric layer 18 and the first dielectric layer 16. Thus, the first dielectric layer 16 and the second dielectric layer 18 may be bonded together to collectively form a dielectric structure 19 in the reducing atmosphere at the temperature of between 130° C. and 170° C. (e.g., at 150° C.) . It is noted that dielectric structure 19 is still in a B-stage state. In addition, a portion of the first dielectric layer 16 (or the dielectric structure 19) may extend into a space between the bottom surface 1482 (e.g., the end surface) of the second reflowable material 148 and the top surface 1281 (e.g., an end surface) of the first reflowable material 128.

Then, a reflowing process may be performed to fuse the first reflowable material 128 and the second reflowable material 148 together to collectively form a solder structure 13 as shown in FIG. 1 at a temperature of between 240° C. and 260° C. for 15 minutes. Meanwhile, the dielectric structure 19 may be partially cured.

Then, a fully curing process may be performed to fully cure the dielectric structure 19 as shown in FIG. 1 at a temperature of about 200° C. for 2 hours. Meanwhile, the assembly structure 1 shown in FIG. 1 is formed.

In the illustrated method, the bonding between the first dielectric layer 16 and the second dielectric layer 18 may be formed at a temperature lower than the temperature of the reflowing process. For example, such bonding temperature may be not greater than 150° C. Thus, a warpage of the first electronic device 12 and the second electronic device 14 may be reduced. For example, the warpage of the first electronic device 12 and the second electronic device 14 may be less than 10 μm. In addition, there would not be too much IMC formed in the solder structure 13. Thus, the solder structure 13 is protected against cracking. In addition, the method may improve the void issue during the bonding process. For example, the top surface 31 of the bottom portion 3 may be a void-free interface. Therefore, the yield rate of the assembly structure 1 may be improved.

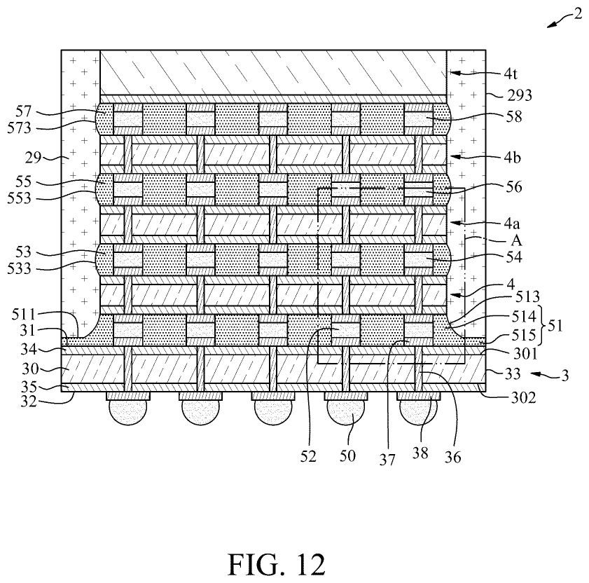

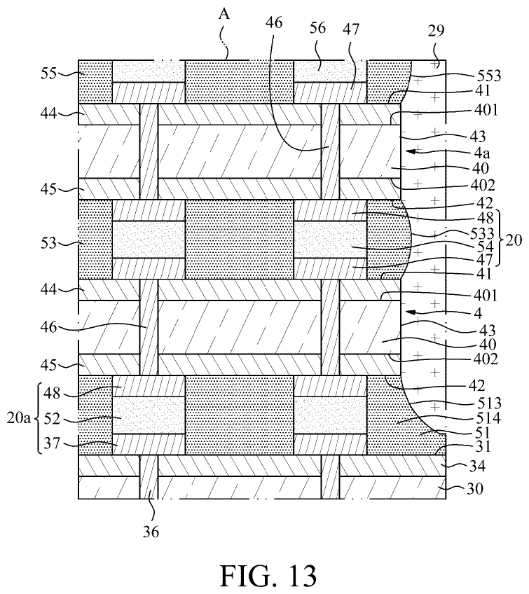

FIG. 12 illustrates a cross-sectional view of an assembly structure 2 according to some embodiments of the present disclosure. FIG. 13 illustrates an enlarged view of an area “A” of FIG. 12. The assembly structure 2 may be an electronic package structure, a semiconductor package structure, an electronic structure, an electronic device or a semiconductor device. The assembly structure 2 may be also referred to as “a three-dimensional form factor device”. The assembly structure 2 may be a high bandwidth memory (HBM). The assembly structure 2 may include a bottom portion 3, a first electronic device 4, a second electronic device 4a, a third electronic device 4b, a top electronic device 4t, a lower solder structure 52, a first solder structure 54, a second solder structure 56, a third solder structure 58, a lower dielectric structure 51, a first dielectric structure 53, a second dielectric structure 55, a third dielectric structure 57, an encapsulant 29 and a plurality of external connectors 50.

The bottom portion 3 may be a substrate, a semiconductor die, a semiconductor chip or an integrated circuit die. The bottom portion 3 may be also referred to as “a first electronic device”. In some embodiments, the bottom portion 3 may be a logic device such as a logic die or a logic chip. In some embodiments, the bottom portion 3 (e.g., the logic device) may include an application-specific integrated circuit (ASIC) chip. The bottom portion 3 may be a controller chip such as an application processor (AP) chip. The bottom portion 3 may be disposed under the first electronic device 4, and may be electrically connected to the first electronic device 4. The bottom portion 3 (or the logic device or the ASIC chip) may have a top surface 31, a bottom surface 32 opposite to the top surface 31, and a lateral surface 33 extending between the top surface 31 and the bottom surface 32. The bottom portion 3 (or the logic device or the ASIC chip) may include a main portion 30, an upper conductive structure 34, a lower conductive structure 35, a plurality of through vias 36, a plurality of upper connectors 37 and a plurality of lower connectors 38.

The main portion 30 may be a semiconductor substrate, and may include, for example, silicon (Si) or other semiconductor materials. The main portion 30 may have a top surface 301 (e.g., an active surface or a backside surface) and a bottom surface 302 (e.g., an active surface or a backside surface) opposite to the top surface 301.

The upper conductive structure 34 may be disposed on the top surface 301 of the main portion 30. A top surface of the upper conductive structure 34 may be the top surface 31 of the bottom portion 3. In some embodiments, the upper conductive structure 34 may include a plurality of front-end-of-line (FEOL) devices, such as resistors, capacitors, inductors, and/or transistors. In some embodiments, the upper conductive structure 34 may further include at least one back-end-of-line (BEOL) interconnect pattern, e.g., a plurality of patterned circuit layers, electrically connected to the front-end-of-line (FEOL) devices. The upper conductive structure 34 may include a dielectric structure, a plurality of circuit layers (including a plurality traces and a plurality of pads) embedded in the dielectric structure, and a plurality of inner vias. The dielectric structure may be a multi-layer film stack deposited on the main portion 30. The inner vias may be disposed in the dielectric structure, and may connect the circuit layers. The dielectric structure of the upper conductive structure 34 may include inorganic material or organic material. In some embodiments, the upper conductive structure 34 may be or may include a single dielectric layer.

The upper connectors 37 (e.g., upper pads) may be disposed on or may protrude from the upper conductive structure 34. The upper connectors 37 may be disposed on or may protrude from the top surface 31 of the bottom portion 3. The upper connectors 37 may extend beyond the top surface 31 of the bottom portion 3. The upper connectors 37 may be portions of a circuit layer.

The lower conductive structure 35 may be disposed on the bottom surface 302 of the main portion 30. A bottom surface of the lower conductive structure 35 may be the bottom surface 32 of the bottom portion 3. In some embodiments, the lower conductive structure 35 may include a plurality of front-end-of-line (FEOL) devices and at least one back-end-of-line (BEOL) interconnect pattern. The lower conductive structure 35 may include a dielectric structure, a plurality of circuit layers (including a plurality traces and a plurality of pads) embedded in the dielectric structure, and a plurality of inner vias. The dielectric structure may be a multi-layer film stack deposited on the main portion 30. The inner vias may be disposed in the dielectric structure, and may connect the circuit layers. The dielectric structure of the lower conductive structure 35 may include inorganic material or organic material. In some embodiments, the lower conductive structure 35 may be or may include a single dielectric layer.

The lower connectors 38 (e.g., lower pads) may be disposed on or may protrude from the lower conductive structure 35. The lower connectors 38 may be disposed on or may protrude from the bottom surface 32 of the bottom portion 3. The lower connectors 38 may extend beyond the bottom surface 32 of the bottom portion 3. The lower connectors 38 may be portions of a circuit layer.

The through vias 36 may extend through the main portion 30, the upper conductive structure 34 and the lower conductive structure 35. The through vias 36 may be also referred to as “through silicon vias (TSVs)”. The through vias 36 may physically connect and electrically connect the upper connectors 37 and the lower connectors 38. Thus, the upper connectors 37 may be electrically connected to the lower connectors 38 through the through vias 36.

The first electronic device 4 may be disposed over the bottom portion 3. The first electronic device 4 may be also referred to as “a second electronic device”. The first electronic device 4 may be or may include a semiconductor chip such as a memory chip. The first electronic device 4 may be or may include a dynamic random access memory (DRAM) chip.

Referring to FIG. 13, the first electronic device 4 may have a top surface 41, a bottom surface 42 opposite to the top surface 41, and a lateral surface 43 extending between the top surface 41 and the bottom surface 42. The first electronic device 4 may include a first main portion 40, a first upper conductive structure 44, a first lower conductive structure 45, a plurality of first through vias 46, a plurality of first upper connectors 47 and a plurality of first lower connectors 48.

The first main portion 40 may be a semiconductor substrate, and may include, for example, silicon (Si) or other semiconductor materials. The first main portion 40 may have a top surface 401 (e.g., an active surface or a backside surface) and a bottom surface 402 (e.g., an active surface or a backside surface) opposite to the top surface 401.

The first upper conductive structure 44 may be disposed on the top surface 401 of the first main portion 40. A top surface of the first upper conductive structure 44 may be the top surface 41 of the first electronic device 4. In some embodiments, the first upper conductive structure 44 may include a plurality of front-end-of-line (FEOL) devices and at least one back-end-of-line (BEOL) interconnect pattern. The first upper conductive structure 44 may include a dielectric structure, a plurality of circuit layers (including a plurality traces and a plurality of pads) embedded in the dielectric structure, and a plurality of inner vias. The dielectric structure may be a multi-layer film stack deposited on the main portion 40. The inner vias may be disposed in the dielectric structure, and may connect the circuit layers. The dielectric structure of the first upper conductive structure 44 may include inorganic material or organic material. In some embodiments, the first upper conductive structure 44 may be or may include a single dielectric layer.

The first upper connectors 47 (e.g., first upper pads) may be disposed on or may protrude from the first upper conductive structure 44. The first upper connectors 47 may be disposed on or may protrude from the top surface 41 of the first electronic device 4. The first upper connectors 47 may extend beyond the top surface 41 of the first electronic device 4. The first upper connectors 47 may be portions of a circuit layer.

The first lower conductive structure 45 may be disposed on the bottom surface 402 of the first main portion 40. A bottom surface of the first lower conductive structure 45 may be the bottom surface 42 of the first electronic device 4. In some embodiments, the first lower conductive structure 45 may include a plurality of front-end-of-line (FEOL) devices and at least one back-end-of-line (BEOL) interconnect pattern. The first lower conductive structure 45 may include a dielectric structure, a plurality of circuit layers (including a plurality traces and a plurality of pads) embedded in the dielectric structure, and a plurality of inner vias. The dielectric structure may be a multi-layer film stack deposited on the main portion 40. The inner vias may be disposed in the dielectric structure, and may connect the circuit layers. The dielectric structure of the first lower conductive structure 45 may include inorganic material or organic material. In some embodiments, the first lower conductive structure 45 may be or may include a single dielectric layer.

The first lower connectors 48 (e.g., lower pads) may be disposed on or may protrude from the first lower conductive structure 45. The first lower connectors 48 may be disposed on or may protrude from the bottom surface 42 of the first electronic device 4. The first lower connectors 48 may extend beyond the bottom surface 42 of the first electronic device 4. The first lower connectors 48 may be portions of a circuit layer.

The first through vias 46 may extend through the first main portion 40, the first upper conductive structure 44 and the first lower conductive structure 45. The first through vias 46 may be also referred to as “through silicon vias (TSVs)”. The first through vias 46 may physically connect and electrically connect the first upper connectors 47 and the first lower connectors 48. Thus, the first upper connectors 47 may be electrically connected to the first lower connectors 48 through the first through vias 46.

The first lower connector 48 of the first electronic device 4 is electrically connected to the upper connector 37 of the bottom portion 3 through the lower solder structure 52 to collectively form a lower conductive portion 20a (e.g., a joint structure). The lower conductive portion 20a may include the first lower connector 48 (e.g., lower pads), the lower solder structure 52 and the upper connector 37 (e.g., upper pad). The lower conductive portion 20a may connect the first electronic device 4 and the bottom portion 3 (or the logic device). The lower solder structure 52 may include or may be formed from a solder material or a reflowable material such as Sn/Ag alloy. A lateral surface of the lower solder structure 52 may be a substantially flat surface. The lower solder structure 52 may be a single layer or a monolithic structure that is full of intermetallic compound (IMC). The lower solder structure 52 may be a full IMC structure with a single IMC or multiple IMCs.

The lower dielectric structure 51 may encapsulate the lower conductive portion 20a. The lower dielectric structure 51 may include or may be formed from an organic material such as polyimide (PI), benzocyclobutene (BCB) or polybenzoxazoles (PBO). The lower dielectric structure 51 may not include fillers. The lower dielectric structure 51 may be disposed between and may contact the first lower conductive structure 45 of the first electronic device 4 and the upper conductive structure 34 of the bottom portion 3 (or the logic device).

The lower dielectric structure 51 may extend beyond the lateral surface 43 of the first electronic device 4. The lower dielectric structure 51 may include a main portion 514 and an extending portion 515 extending from the main portion 514. A lateral surface 513 of the main portion 514 may be a curved surface. The main portion 514 may be a raised feature with respect to the extending portion 515. The extending portion 515 may be disposed between the encapsulant 29 and the top surface 31 of the bottom portion 3. A top surface 511 of the extending portion 515 may be substantially parallel with the top surface 31 of the bottom portion 3. The extending portion 515 may have a wrinkled top surface 511 from a top view. A lateral surface of the extending portion 515 may be substantially aligned with the lateral surface 33 of the bottom portion 3 (or the logic device) and a lateral surface 293 of the encapsulant 29.

The second electronic device 4a, the third electronic device 4b and the top electronic device 4t may be disposed over or may be stacked on the first electronic device 4. Each of the second electronic device 4a, the third electronic device 4b and the top electronic device 4t may be or may include a semiconductor chip such as a memory chip. Each of the second electronic device 4a, the third electronic device 4b and the top electronic device 4t may be or may include a dynamic random access memory (DRAM) chip.

The structure of the second electronic device 4a may be the same as the structure of the first electronic device 4. The second electronic device 4a may have a top surface 41, a bottom surface 42 opposite to the top surface 41, and a lateral surface 43 extending between the top surface 41 and the bottom surface 42. The second electronic device 4a may include a second main portion 40, a second upper conductive structure 44, a second lower conductive structure 45, a plurality of second through vias 46, a plurality of second upper connectors 47 and a plurality of second lower connectors 48.

The second main portion 40 may have a top surface 401 (e.g., an active surface or a backside surface) and a bottom surface 402 (e.g., an active surface or a backside surface) opposite to the top surface 401. The second upper conductive structure 44 may be disposed on the top surface 401 of the second main portion 40. In some embodiments, the second upper conductive structure 44 may be the same as the first upper conductive structure 44. The second upper connectors 47 (e.g., second upper pads) may be disposed on or may protrude from the second upper conductive structure 44.

The second lower conductive structure 45 may be disposed on the bottom surface 402 of the second main portion 40. In some embodiments, the second lower conductive structure 45 may be the same as the first lower conductive structure 45. The second lower connectors 48 (e.g., lower pads) may be disposed on or may protrude from the second lower conductive structure 45. The second through vias 46 may extend through the second main portion 40, the second upper conductive structure 44 and the second lower conductive structure 45. The second through vias 46 may physically connect and electrically connect the second upper connectors 47 and the second lower connectors 48.

The second lower connector 48 of the second electronic device 4a is electrically connected to the first upper connector 47 of the first electronic device 4 through the first solder structure 54 to collectively form a first conductive portion 20 (e.g., a joint structure). The first conductive portion 20 may include the second lower connector 48 (e.g., lower pads), the first solder structure 54 and the first upper connector 47 (e.g., upper pads). The first conductive portion 20 may connect the second electronic device 4a and the first electronic device 4. The first solder structure 54 may the same as the lower solder structure 52.

The first dielectric structure 53 may encapsulate the first conductive portion 20. The first dielectric structure 53 may include or may be formed from an organic material such as polyimide (PI), benzocyclobutene (BCB) or polybenzoxazoles (PBO). The first dielectric structure 53 may not include fillers. The first dielectric structure 53 may be disposed between and may contact the second lower conductive structure 45 of the second electronic device 4a and the first upper conductive structure 44 of the first electronic device 4.

The first dielectric structure 53 may extend beyond the lateral surface 43 of the first electronic device 4 and the lateral surface 43 of the second electronic device 4a. A lateral surface 533 of the first dielectric structure 53 may be a convex surface. The first dielectric structure 53 may be a single layer or a monolithic structure that is full of cured organic material. A shape and a curvature of the lateral surface 513 of the lower dielectric structure 51 may be different from a shape and a curvature of the lateral surface 533 of the first dielectric structure 53.

The third electronic device 4b may be disposed over or may be stacked on the second electronic device 4a. The structure of the third electronic device 4b may be the same as the structure of the second electronic device 4a. The third electronic device 4b may be electrically connected to the second electronic device 4a through the second solder structure 56. The second dielectric structure 55 may encapsulate the second conductive portion including the third lower connector 48 of the third electronic device 4b, the second solder structure 56 and the second upper connector 47 of the second electronic device 4a. A lateral surface 553 of the second dielectric structure 55 may be a convex surface.

The top electronic device 4t may be disposed over or may be stacked on the third electronic device 4b. The structure of the top electronic device 4t may be similar to the structure of the third electronic device 4b except that the top electronic device 4t does not include the upper conductive structure, the through vias and the upper connectors. The top electronic device 4t may be electrically connected to the third electronic device 4b through the third solder structure 58. The third dielectric structure 57 may encapsulate the third conductive portion including the fourth lower connector of the top electronic device 4t, the third solder structure 58 and the third upper connector of the third electronic device 4b. A lateral surface 573 of the third dielectric structure 57 may be a convex surface.

The encapsulant 29 may be a molding compound with or without fillers. The encapsulant 29 may encapsulate the bottom portion 3, the first electronic device 4, the second electronic device 4a, the third electronic device 4b, the top electronic device 4t, the lower dielectric structure 51, the first dielectric structure 53, the second dielectric structure 55 and the third dielectric structure 57. The encapsulant 29 may be separated from the bottom portion 3 by the extending portion 515 of the lower dielectric structure 51.

The external connectors 50 may be formed or disposed on the lower connectors 38 (e.g., lower pads) of the bottom portion 3. Each of the external connector 50 may be a solder material, a solder bump, a conductive connector, a reflowable connector, or a reflowable material. The external connectors 50 may include controlled collapse chip connectors.

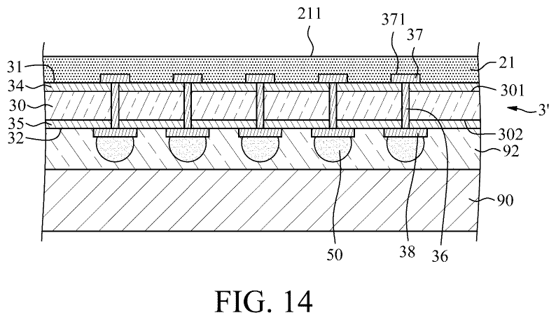

FIG. 14 through FIG. 31 illustrate a manufacturing method for manufacturing an assembly structure according to some embodiments of the present disclosure. In some embodiments, the method is for manufacturing the assembly structure 2 shown in FIG. 12.

Referring to FIG. 14, a carrier 90 may be provided, and a release layer 92 may be formed or disposed on a surface of the carrier 90. The carrier 90 may be a glass substrate or a FR4 substrate. The carrier 90 may be in a panel type (or a panel structure) or a wafer type (or a wafer structure). Then, a bottom portion 3′ may be formed or disposed on the release layer 92 on the carrier 90. The bottom portion 3′ of FIG. 14 may be the same as the bottom portion 3 of FIG. 12. The lower connectors 38 (e.g., lower pads) of the bottom portion 3′ and the external connectors 50 may be embedded in the release layer 92. Then, a dielectric layer 21 may be formed or disposed on the top surface 31 of the bottom portion 3′ to cover the upper connectors 37 (e.g., upper pads) by coating. The dielectric layer 21 may include an organic material such as polyimide (PI), benzocyclobutene (BCB) or polybenzoxazoles (PBO). The top surface 211 (e.g., an outer surface) of the dielectric layer 21 may be higher than the top surface 371 (e.g., the end surface) of the upper connector 37 (e.g., upper pad). Then, the dielectric layer 21 may be pre-cured, for example, at a temperature of 140° C. for 30 minutes, so that the dielectric layer 21 is in a B-stage state.

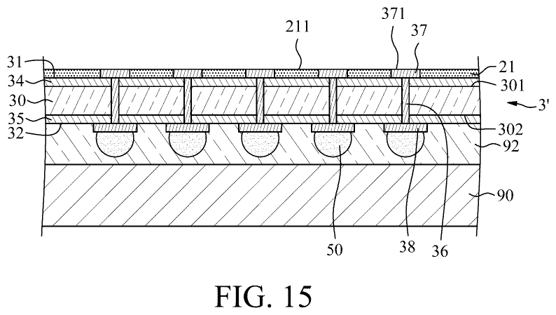

Referring to FIG. 15, a grinding process (e.g., a chemical mechanical polishing (CMP) process) may be conducted on the top surface 211 of the dielectric layer 21. Thus, an upper portion of the dielectric layer 21 and an upper portion of the upper connector 37 may be removed concurrently. After the grinding process, the top surface 371 (e.g., the end surface) of the upper connector 37 may be substantially aligned with the top surface 211 (e.g., the outer surface) of the dielectric layer 21. The upper connector 37 may be embedded in the dielectric layer 21. The top surface 371 (e.g., the end surface) of the upper connector 37 may be exposed by the top surface 211 (e.g., the outer surface) of the dielectric layer 21.

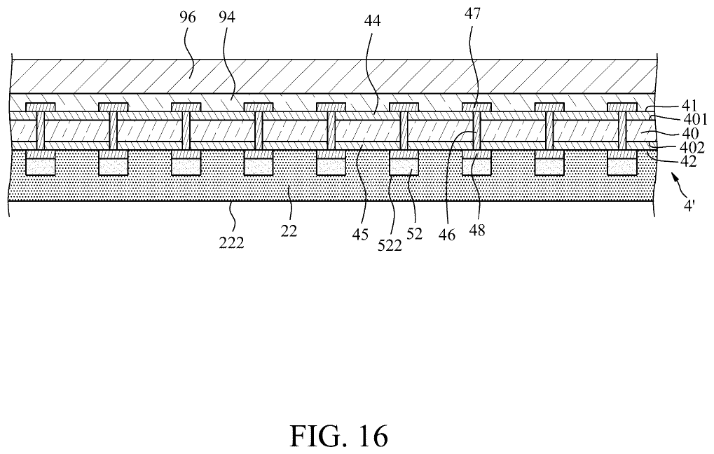

Referring to FIG. 16, a carrier 96 may be provided, and a release layer 94 may be formed or disposed on a surface of the carrier 96. The carrier 96 may be a glass substrate or a FR4 substrate. The carrier 96 may be in a panel type (or a panel structure) or a wafer type (or a wafer structure). Then, a first electronic device 4′ may be formed or disposed on the release layer 94 on the carrier 96. The first electronic device 4′ of FIG. 16 may be the same as the first electronic device 4 of FIG. 12.

The first upper connectors 47 (e.g., upper pads) of the first electronic device 4′ may be embedded in the release layer 94. Then, a plurality of lower reflowable materials 52 may be formed or disposed on the first lower connectors 48 (e.g., lower pads). Then, a first lower dielectric layer 22 may be formed or disposed on the bottom surface 42 of the first electronic device 4′ to cover the lower reflowable material 52 by coating. The first lower dielectric layer 22 may include an organic material such as polyimide (PI), benzocyclobutene (BCB) or polybenzoxazoles (PBO). The bottom surface 222 (e.g., an outer surface) of the first lower dielectric layer 22 may be lower than the bottom surface 522 (e.g., the end surface) of the lower reflowable material 52. Then, the first lower dielectric layer 22 may be pre-cured, for example, at a temperature of 140° C. for 30 minutes, so that the first lower dielectric layer 22 is in a B-stage state.

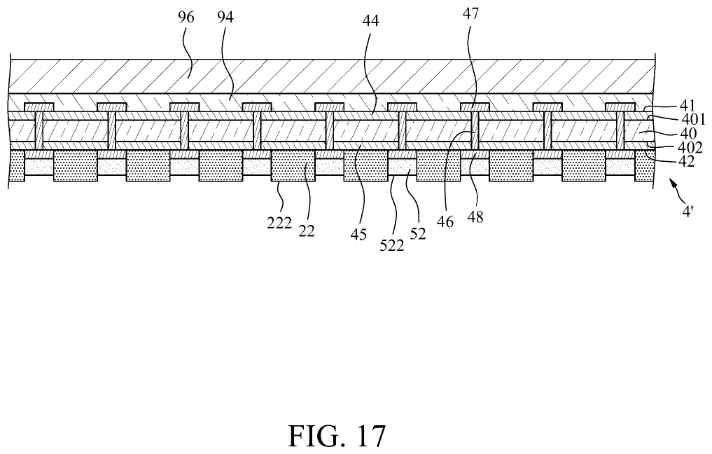

Referring to FIG. 17, a fly-cutting process may be conducted on the bottom surface 222 (e.g., an outer surface) of the first lower dielectric layer 22. After the fly-cutting process, the bottom surface 522 (e.g., the end surface) of the lower reflowable material 52 may be exposed by the bottom surface 222 (e.g., an outer surface) of the first lower dielectric layer 22. In some embodiments, the bottom surface 522 (e.g., the end surface) of the lower reflowable material 52 may be recessed from the bottom surface 222 (e.g., an outer surface) of the first lower dielectric layer 22 by about 100 nm.

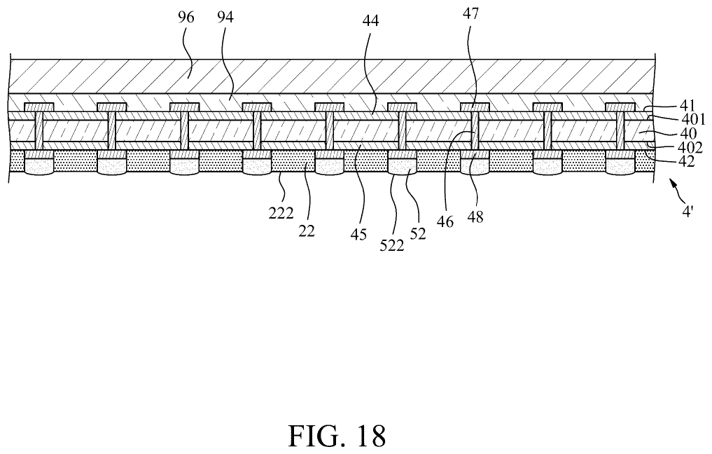

Referring to FIG. 18, the first lower dielectric layer 22 may be etched or thinned by descumming so that the lower reflowable material 52 may protrude from the bottom surface 222 (e.g., an outer surface) of the first lower dielectric layer 22 by less than 1 μm.

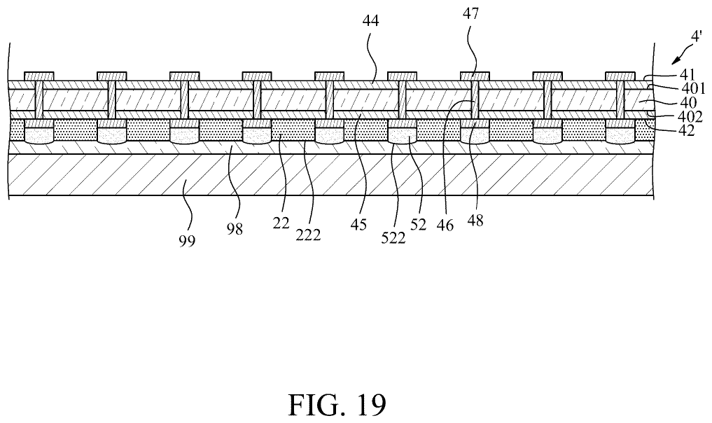

Referring to FIG. 19, the first electronic device 4′ and the first lower dielectric layer 22 may be disposed on a release layer 98 on a carrier 99. Then, the release layer 94 and the carrier 96 may be removed.

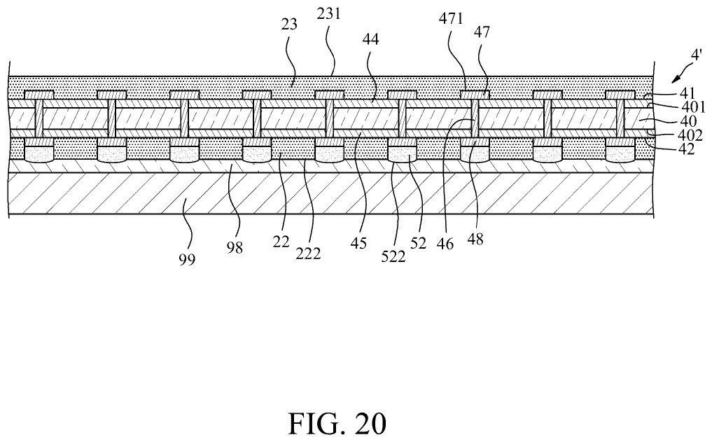

Referring to FIG. 20, a first upper dielectric layer 23 may be formed or disposed on the top surface 41 of the first electronic device 4′ to cover the first upper connectors 47 (e.g., upper pads) by coating. The first upper dielectric layer 23 may include an organic material such as polyimide (PI), benzocyclobutene (BCB) or polybenzoxazoles (PBO). The top surface 231 (e.g., an outer surface) of the first upper dielectric layer 23 may be higher than the top surface 471 (e.g., the end surface) of the first upper connector 47 (e.g., upper pad). Then, the first upper dielectric layer 23 may be pre-cured, for example, at a temperature of 140° C. for 30 minutes, so that the first upper dielectric layer 23 is in a B-stage state.

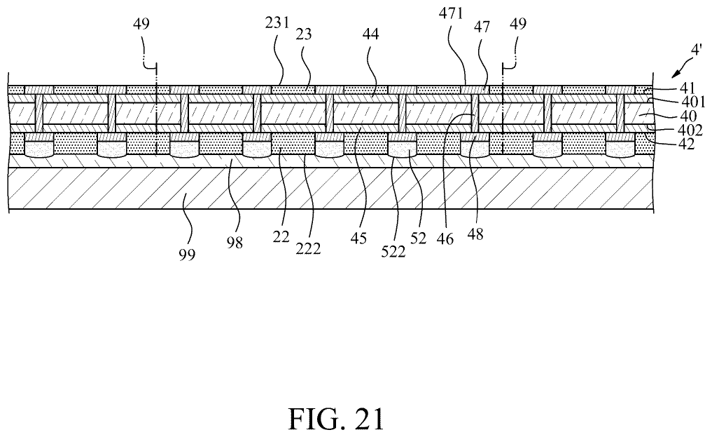

Referring to FIG. 21, a grinding process (e.g., a chemical mechanical polishing (CMP) process) may be conducted on the top surface 231 of the first upper dielectric layer 23. After the grinding process, the top surface 471 (e.g., the end surface) of the first upper connector 47 may be substantially aligned with the top surface 231 (e.g., the outer surface) of the first upper dielectric layer 23. The first upper connector 47 may be embedded in the first upper dielectric layer 23. The top surface 471 (e.g., the end surface) of the first upper connector 47 may be exposed by the top surface 231 (e.g., the outer surface) of the first upper dielectric layer 23.

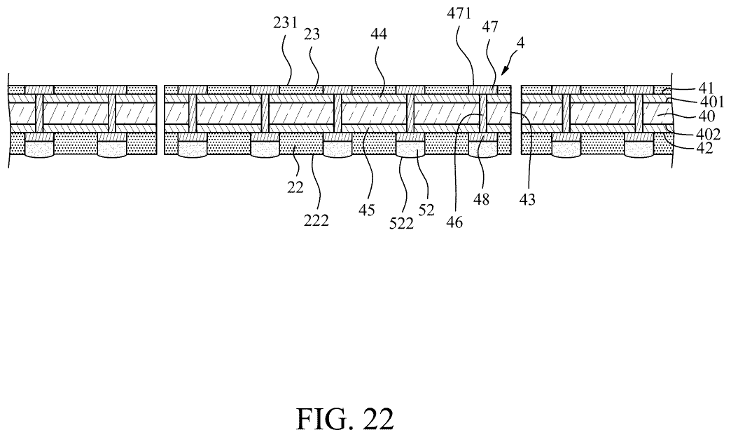

Referring to FIG. 22, a singulation process may be conducted along the cutting lines 49 so as to form a plurality of first electronic devices 4.

The second electronic device 4a and the third electronic device 4b may be manufactured by the method for manufacturing the first electronic device 4.

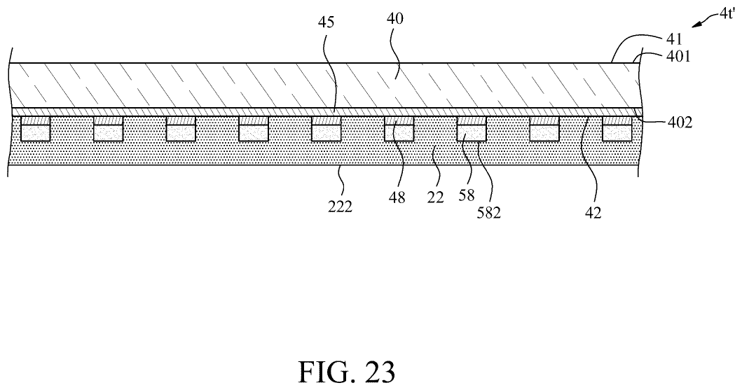

Referring to FIG. 23, a top electronic device 4t′ may be provided. The top electronic device 4t′ of FIG. 23 may be the same as the top electronic device 4t of FIG. 12. Then, a dielectric layer 22 may be formed or disposed on the bottom surface 42 of the top electronic device 4t′ to cover the third reflowable material 58 by coating. The dielectric layer 22 may include an organic material such as polyimide (PI), benzocyclobutene (BCB) or polybenzoxazoles (PBO). The bottom surface 222 (e.g., an outer surface) of the dielectric layer 22 may be lower than the bottom surface 582 (e.g., the end surface) of the third reflowable material 58. Then, the dielectric layer 22 may be pre-cured, for example, at a temperature of 140° C. for 30 minutes, so that the dielectric layer 22 is in a B-stage state.

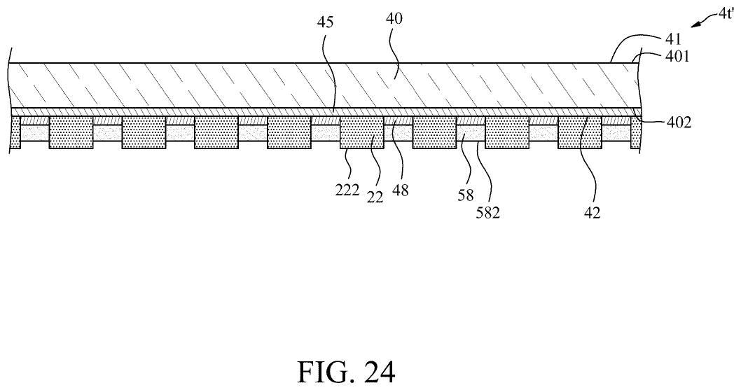

Referring to FIG. 24, a fly-cutting process may be conducted on the bottom surface 222 (e.g., an outer surface) of the dielectric layer 22. After the fly-cutting process, the bottom surface 582 (e.g., the end surface) of the third reflowable material 58 may be exposed by the bottom surface 222 (e.g., an outer surface) of the dielectric layer 22. In some embodiments, the bottom surface 582 (e.g., the end surface) of the third reflowable material 58 may be recessed from the bottom surface 222 (e.g., an outer surface) of the dielectric layer 22 by about 100 nm.

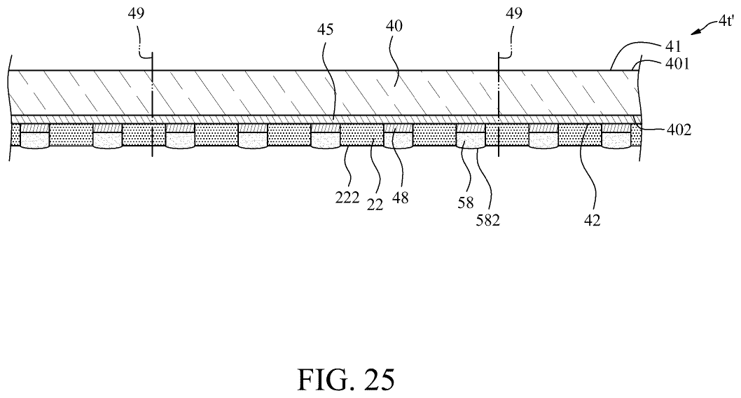

Referring to FIG. 25, the dielectric layer 22 may be etched or thinned by descumming so that the third reflowable material 58 may protrude from the bottom surface 222 (e.g., an outer surface) of the dielectric layer 22 by less than 1 μm.

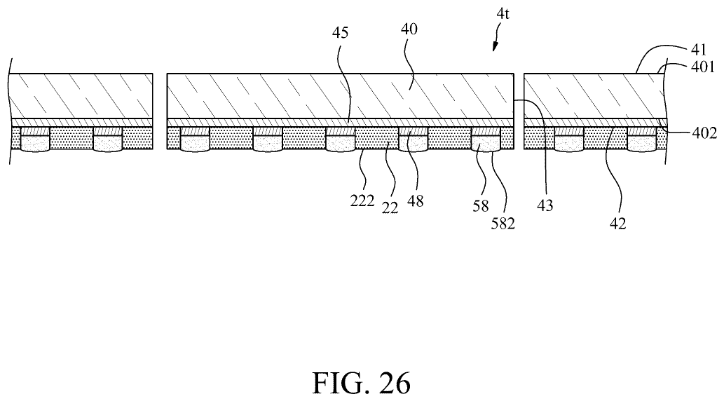

Referring to FIG. 26, a singulation process may be conducted along the cutting lines 49 so as to form a plurality of top electronic devices 4t.

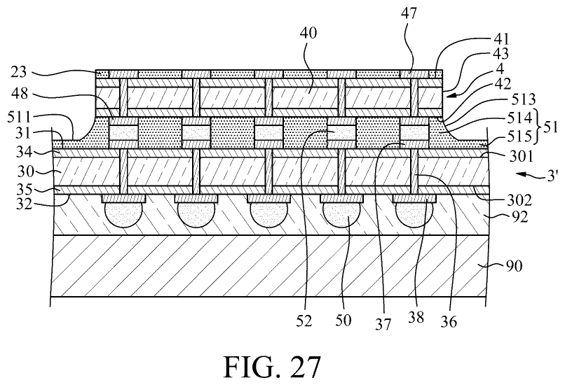

Referring to FIG. 27, the first electronic device 4 of FIG. 22 may be bonded to the bottom portion 3′ of FIG. 15. For example, a bonding may be performed between the dielectric layer 21 and the first lower dielectric layer 22 in the reducing atmosphere at a temperature of between 130° C. and 170° C. (e.g., at 150° C.) . Thus, the dielectric layer 21 and the first lower dielectric layer 22 may be bonded together to collectively form a lower dielectric structure 51. It is noted that the lower dielectric structure 51 is still in a B-stage state. Then, a reflowing process may be performed to bond the lower reflowable material 52 to the upper connector 37 to form a lower solder structure 52 at a temperature of between 240° C. and 260° C. for 15 minutes. Then, a fully curing process may be performed to fully cure the lower dielectric structure 51 at a temperature of about 200° C. for 2 hours.

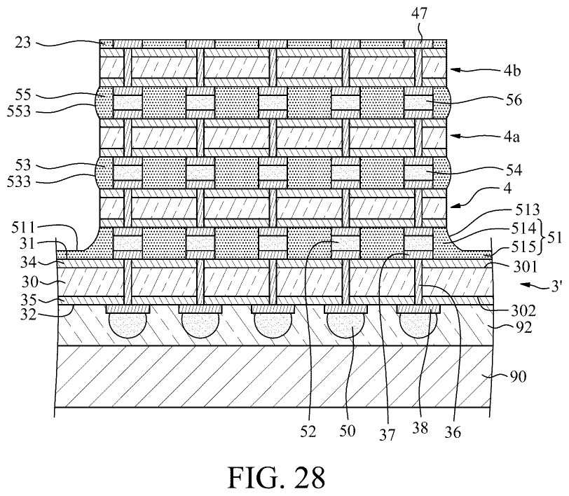

Referring to FIG. 28, the second electronic device 4a may be bonded to the first electronic device 4. The third electronic device 4b may be bonded to the second electronic device 4a.

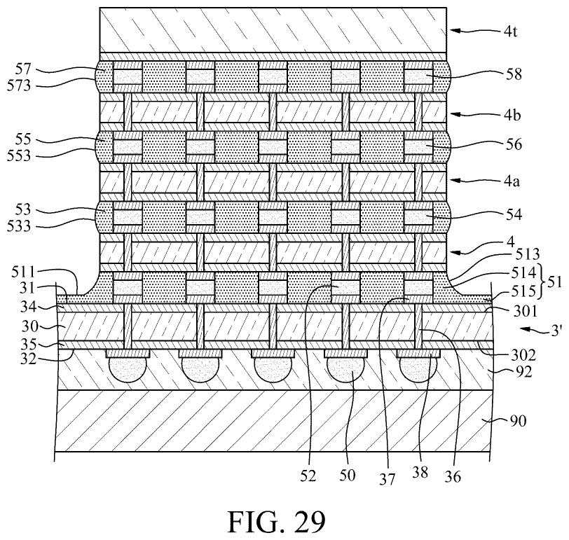

Referring to FIG. 29, the top electronic device 4t may be bonded to the third electronic device 4b.

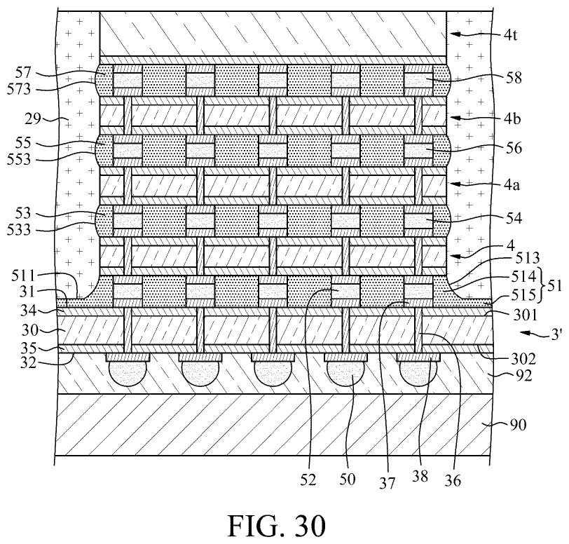

Referring to FIG. 30, an encapsulant 29 may be formed on the lateral surface 513 of the main portion 514 of the lower dielectric structure 51 and the top surface 511 of the extending portion 515 of the lower dielectric structure 51 on the top surface 31 of the bottom portion 3′ to encapsulate and cover the first electronic device 4, the second electronic device 4a, the third electronic device 4b and the top electronic device 4t.

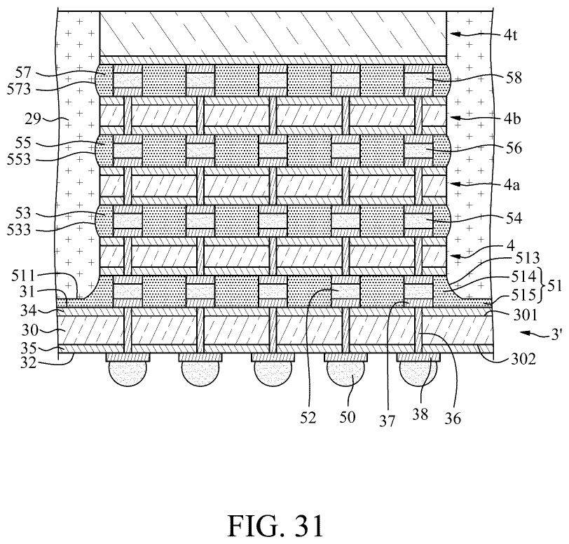

Referring to FIG. 31, the release layer 92 and the carrier 90 may be removed.

Then, a singulation process may be conducted so as to form a plurality of assembly structures 1 shown in FIG. 1.

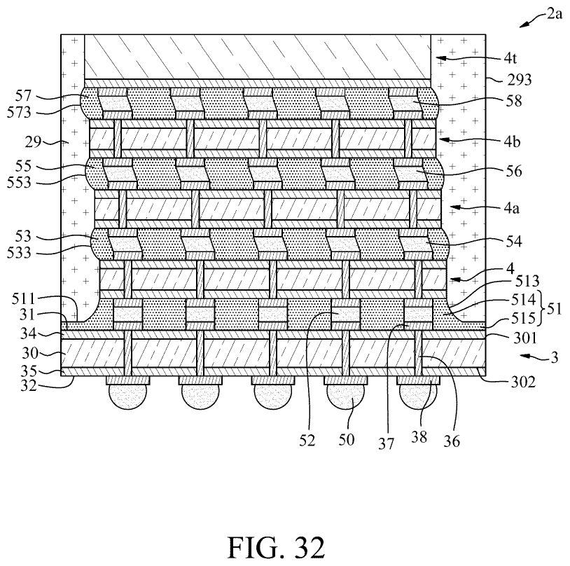

FIG. 32 illustrates a cross-sectional view of an assembly structure 2a according to some embodiments of the present disclosure. The assembly structure 2a of FIG. 32 is similar to the assembly structure 2 of FIG. 12 except that the second electronic device 4a may be misaligned with the first electronic device 4, the third electronic device 4b may be misaligned with the second electronic device 4a, and the top electronic device 4t may be misaligned with the third electronic device 4b. The first main portion 40 of the first electronic device 4 and the second main portion 40 of the second electronic device 4a may form a stepped configuration. The first solder structure 54, the second solder structure 56 and the third solder structure 58 may have tilted sidewalls.

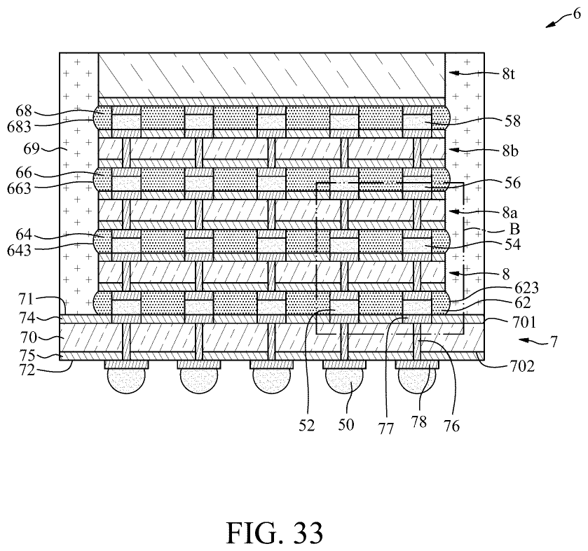

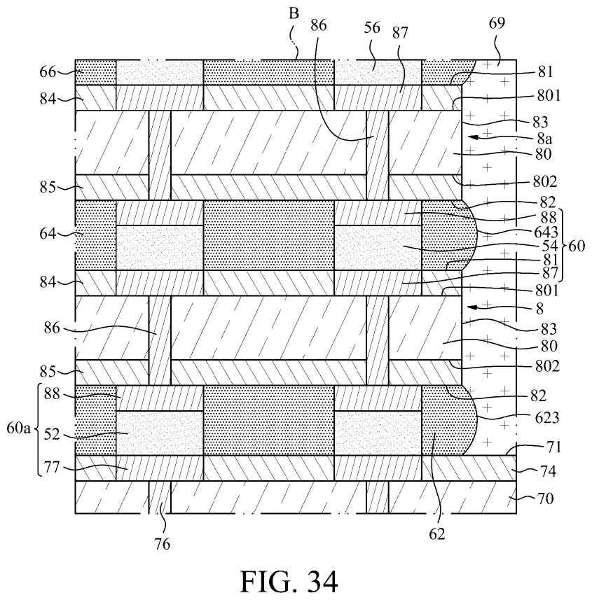

FIG. 33 illustrates a cross-sectional view of an assembly structure 6 according to some embodiments of the present disclosure. FIG. 34 illustrates an enlarged view of an area “B” of FIG. 33. The assembly structure 6 of FIG. 33 and FIG. 34 is similar to the assembly structure 2 of FIG. 12 and FIG. 13. The assembly structure 6 may include a bottom portion 7, a first electronic device 8, a second electronic device 8a, a third electronic device 8b, a top electronic device 8t, a lower solder structure 52, a first solder structure 54, a second solder structure 56, a third solder structure 58, a lower dielectric structure 62, a first dielectric structure 64, a second dielectric structure 66, a third dielectric structure 68, an encapsulant 69 and a plurality of external connectors 50.

The bottom portion 7 of FIG. 33 and FIG. 34 is similar to the bottom portion 3 of FIG. 12 and FIG. 13. The bottom portion 7 may have a top surface 71, a bottom surface 72 opposite to the top surface 71, and a lateral surface 73 extending between the top surface 71 and the bottom surface 72. The bottom portion 7 may include a main portion 70, an upper conductive structure 74, a lower conductive structure 75, a plurality of through vias 76, a plurality of upper connectors 77 and a plurality of lower connectors 78.

The main portion 70 may have a top surface 701 and a bottom surface 702 opposite to the top surface 701. The upper conductive structure 74 may be disposed on the top surface 701 of the main portion 70. A top surface of the upper conductive structure 74 may be the top surface 71 of the bottom portion 7. In some embodiments, the upper conductive structure 74 may include a plurality of front-end-of-line (FEOL) devices and at least one back-end-of-line (BEOL) interconnect pattern. The upper conductive structure 74 may include a dielectric structure, a plurality of circuit layers (including a plurality traces and a plurality of pads) embedded in the dielectric structure, and a plurality of inner vias. The dielectric structure may be a multi-layer film stack deposited on the main portion 70. The inner vias may be disposed in the dielectric structure, and may connect the circuit layers. The dielectric structure of the upper conductive structure 74 may include inorganic material or organic material. In some embodiments, the upper conductive structure 74 may be or may include a single dielectric layer.

The upper connectors 77 (e.g., upper pads) may be disposed on the top surface 701 of the main portion 70. The upper connectors 77 may be embedded in the upper conductive structure 74 of the bottom portion 7, and may be exposed by the top surface 71 of the bottom portion 7. The top surface 771 of the upper connector 77 is substantially aligned with the top surface 71 of the bottom portion 7.

The lower conductive structure 75 may be disposed on the bottom surface 702 of the main portion 70. In some embodiments, the lower conductive structure 75 may include a plurality of front-end-of-line (FEOL) devices and at least one back-end-of-line (BEOL) interconnect pattern. The lower conductive structure 75 may include a dielectric structure, a plurality of circuit layers (including a plurality traces and a plurality of pads) embedded in the dielectric structure, and a plurality of inner vias. The dielectric structure may be a multi-layer film stack deposited on the main portion 70. The inner vias may be disposed in the dielectric structure, and may connect the circuit layers. The dielectric structure of the lower conductive structure 75 may include inorganic material or organic material. In some embodiments, the lower conductive structure 75 may be or may include a single dielectric layer.

The lower connectors 78 (e.g., lower pads) may be disposed on or may protrude from the lower conductive structure 75. The lower connectors 78 may be disposed on or may protrude from the bottom surface 72 of the bottom portion 7. The lower connectors 78 may extend beyond the bottom surface 72 of the bottom portion 7. The upper connectors 77 may be electrically connected to the lower connectors 78 through the through vias 76.

The first electronic device 8 may be disposed over the bottom portion 7. The first electronic device 7 may be also referred to as “a second electronic device”. The first electronic device 8 may be or may include a semiconductor chip such as a memory chip. The first electronic device 8 may be or may include a dynamic random access memory (DRAM) chip.

Referring to FIG. 34, the first electronic device 8 may have a top surface 81, a bottom surface 82 opposite to the top surface 81, and a lateral surface 83 extending between the top surface 81 and the bottom surface 82. The first electronic device 8 may include a first main portion 80, a first upper conductive structure 84, a first lower conductive structure 85, a plurality of first through vias 86, a plurality of first upper connectors 87 and a plurality of first lower connectors 88.

The first main portion 80 may be a semiconductor substrate, and may include, for example, silicon (Si) or other semiconductor materials. The first main portion 80 may have a top surface 801 and a bottom surface 802 opposite to the top surface 801.

The first upper conductive structure 84 may be disposed on the top surface 801 of the first main portion 80. A top surface of the first upper conductive structure 84 may be the top surface 81 of the first electronic device 8. In some embodiments, the first upper conductive structure 84 may include a plurality of front-end-of-line (FEOL) devices and at least one back-end-of-line (BEOL) interconnect pattern. The first upper conductive structure 84 may include a dielectric structure, a plurality of circuit layers (including a plurality traces and a plurality of pads) embedded in the dielectric structure, and a plurality of inner vias. The dielectric structure may be a multi-layer film stack deposited on the main portion 80. The inner vias may be disposed in the dielectric structure, and may connect the circuit layers. The dielectric structure of the first upper conductive structure 84 may include inorganic material or organic material. In some embodiments, the first upper conductive structure 84 may be or may include a single dielectric layer.

The first upper connectors 87 (e.g., first upper pads) may be disposed on the top surface 801 of the first main portion 80. The first upper connectors 87 may be embedded in the first upper conductive structure 84 of the first electronic device 8, and may be exposed by the top surface 81 of the first electronic device 8. The top surface 871 of the first upper connector 87 is substantially aligned with the top surface 81 of the first electronic device 8 (i.e., the top surface 841 of the first upper conductive structure 84).

The first lower conductive structure 85 may be disposed on the bottom surface 802 of the first main portion 80. A bottom surface of the first lower conductive structure 85 may be the bottom surface 82 of the first electronic device 8. In some embodiments, the first lower conductive structure 85 may include a plurality of front-end-of-line (FEOL) devices and at least one back-end-of-line (BEOL) interconnect pattern. In some embodiments, the first lower conductive structure 85 may be or may include a single dielectric layer.

The first lower connectors 88 (e.g., lower pads) may be disposed on or may protrude from the first lower conductive structure 85. The first lower connectors 88 may be disposed on or may protrude from the bottom surface 82 of the first electronic device 8. The first lower connectors 88 may extend beyond the bottom surface 82 of the first electronic device 8. The first upper connectors 87 may be electrically connected to the first lower connectors 88 through the first through vias 86.

The first lower connector 88 of the first electronic device 8 is electrically connected to the upper connector 77 of the bottom portion 7 through the lower solder structure 52 to collectively form a lower conductive portion 60a (e.g., a joint structure). The lower conductive portion 60a may include the first lower connector 88 (e.g., lower pads), the lower solder structure 52 and the upper connector 77 (e.g., upper pad). The lower conductive portion 60a may connect the first electronic device 8 and the bottom portion 7.

The lower dielectric structure 62 may encapsulate the lower conductive portion 60a. The lower dielectric structure 62 may include or may be formed from an organic material such as polyimide (PI), benzocyclobutene (BCB) or polybenzoxazoles (PBO). The lower dielectric structure 62 may not include fillers. The lower dielectric structure 62 may be disposed between and may contact the first lower conductive structure 85 of the first electronic device 8 and the upper conductive structure 74 of the bottom portion 7.

The lower dielectric structure 62 may extend beyond the lateral surface 83 of the first electronic device 8. A lateral surface 623 of the lower dielectric structure 62 may be a convex surface.

The second electronic device 8a, the third electronic device 8b and the top electronic device 8t may be disposed over or may be stacked on the first electronic device 8. Each of the second electronic device 8a, the third electronic device 8b and the top electronic device 8t may be or may include a semiconductor chip such as a memory chip. Each of the second electronic device 8a, the third electronic device 8b and the top electronic device 8t may be or may include a dynamic random access memory (DRAM) chip.

The structure of the second electronic device 8a may be the same as the structure of the first electronic device 8. The second electronic device 8a may have a top surface 81, a bottom surface 82 opposite to the top surface 81, and a lateral surface 83 extending between the top surface 81 and the bottom surface 82. The second electronic device 8a may include a second main portion 80, a second upper conductive structure 84, a second lower conductive structure 85, a plurality of second through vias 86, a plurality of second upper connectors 87 and a plurality of second lower connectors 88.

The second main portion 80 may have a top surface 801 and a bottom surface 802 opposite to the top surface 801. The second upper conductive structure 84 may be disposed on the top surface 801 of the second main portion 80. In some embodiments, the second upper conductive structure 84 may be the same as the first upper conductive structure 84. The second upper connectors 87 may be embedded in the second upper conductive structure 44. The top surface of the second upper connector 87 is substantially aligned with the top surface 81 of the second electronic device 8a.

The second lower conductive structure 85 may be disposed on the bottom surface 802 of the second main portion 80. The second lower connectors 88 (e.g., lower pads) may be disposed on or may protrude from the second lower conductive structure 85. The second through vias 86 may physically connect and electrically connect the second upper connectors 87 and the second lower connectors 88.

The second lower connector 88 of the second electronic device 8a is electrically connected to the first upper connector 87 of the first electronic device 8 through the first solder structure 54 to collectively form a first conductive portion 60 (e.g., a joint structure). The first conductive portion 60 may include the second lower connector 88, the first solder structure 54 and the first upper connector 77.

The first dielectric structure 64 may encapsulate the first conductive portion 60. The first dielectric structure 64 may be disposed between and may contact the second lower conductive structure 85 of the second electronic device 8a and the first upper conductive structure 84 of the first electronic device 4. The first dielectric structure 64 may extend beyond the lateral surface 83 of the first electronic device 8 and the lateral surface 83 of the second electronic device 8a. A lateral surface 643 of the first dielectric structure 64 may be a convex surface. The first dielectric structure 64 may be a single layer or a monolithic structure that is full of cured organic material. A shape and a curvature of the lateral surface 623 of the lower dielectric structure 62 may the same as a shape and a curvature of the lateral surface 643 of the first dielectric structure 64.

The third electronic device 8b may be disposed over or may be stacked on the second electronic device 8a. The structure of the third electronic device 8b may be the same as the structure of the second electronic device 8a. The third electronic device 8b may be electrically connected to the second electronic device 8a through the second solder structure 56. The second dielectric structure 66 may encapsulate the second conductive portion including the third lower connector 88 of the third electronic device 8b, the second solder structure 56 and the second upper connector 87 of the second electronic device 8a. A lateral surface 663 of the second dielectric structure 66 may be a convex surface.

The top electronic device 8t may be disposed over or may be stacked on the third electronic device 8b. The structure of the top electronic device 8t may be similar to the structure of the third electronic device 8b except that the top electronic device 8t does not include the upper conductive structure, the through vias and the upper connectors. The top electronic device 8t may be electrically connected to the third electronic device 4b through the third solder structure 58. The third dielectric structure 68 may encapsulate the third conductive portion including the fourth lower connector of the top electronic device 8t, the third solder structure 58 and the third upper connector of the third electronic device 8b. A lateral surface 683 of the third dielectric structure 68 may be a convex surface.

The encapsulant 69 may be a molding compound with or without fillers. The encapsulant 69 may encapsulate the bottom portion 7, the first electronic device 8, the second electronic device 8a, the third electronic device 8b, the top electronic device 8t, the lower dielectric structure 62, the first dielectric structure 64, the second dielectric structure 66 and the third dielectric structure 68. The encapsulant 69 may contact the upper conductive structure 74 of the bottom portion 7 to form an inorganic-to-inorganic bond. The encapsulant 69 may contact the top surface 71 of the bottom portion 7.

The external connectors 50 may be formed or disposed on the lower connectors 78 of the bottom portion 7. Each of the external connector 50 may be a solder material, a solder bump, a conductive connector, a reflowable connector, or a reflowable material.

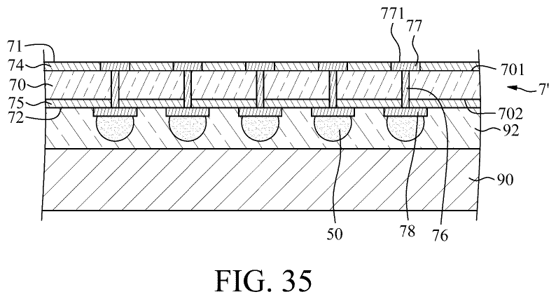

FIG. 35 through FIG. 49 illustrate a manufacturing method for manufacturing an assembly structure according to some embodiments of the present disclosure. In some embodiments, the method is for manufacturing the assembly structure 6 shown in FIG. 33.

Referring to FIG. 35, a bottom portion 7′ may be provided, and may be formed or disposed on a release layer 92 on a carrier 90. The bottom portion 7′ of FIG. 35 may be the same as the bottom portion 7 of FIG. 33. The lower connectors 78 (e.g., lower pads) of the bottom portion 7′ and the external connectors 50 may be embedded in the release layer 92.

The top surface 771 of the upper connector 77 of the bottom portion 7′ is substantially aligned with the top surface 71 of the bottom portion 7′.

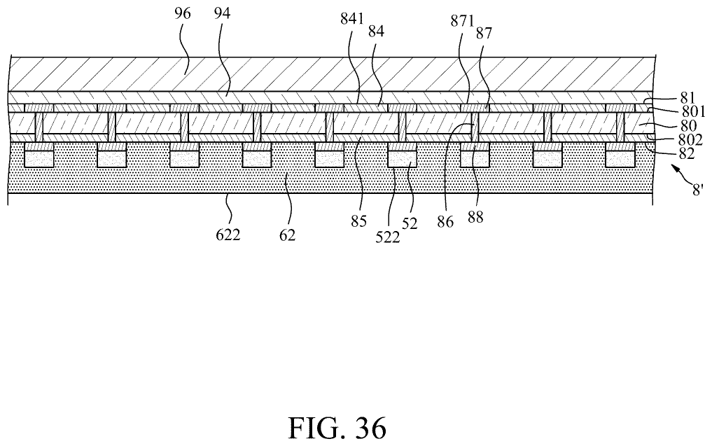

Referring to FIG. 36, a first electronic device 8′ may be formed or disposed on a release layer 94 on a carrier 96. The first electronic device 8′ of FIG. 36 may be the same as the first electronic device 8 of FIG. 33. The top surface 871 of the first upper connector 87 is substantially aligned with the top surface 81 of the first electronic device 8 (i.e., the top surface 841 of the first upper conductive structure 84). Then, a first lower dielectric layer 62 may be formed or disposed on the bottom surface 82 of the first electronic device 8′ to cover the lower reflowable material 52 by coating. The first lower dielectric layer 62 may include an organic material such as polyimide (PI), benzocyclobutene (BCB) or polybenzoxazoles (PBO). The bottom surface 622 of the first lower dielectric layer 62 may be lower than the bottom surface 522 of the lower reflowable material 52. Then, the first lower dielectric layer 62 may be pre-cured, for example, at a temperature of 140° C. for 30 minutes, so that the first lower dielectric layer 62 is in a B-stage state.

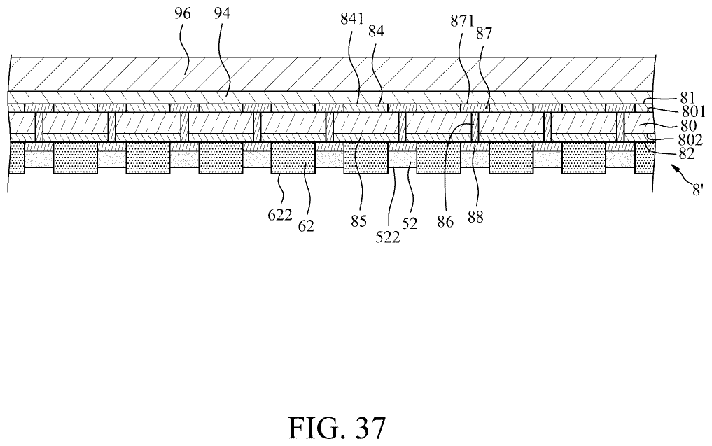

Referring to FIG. 37, a fly-cutting process may be conducted on the bottom surface 622 of the first lower dielectric layer 62. After the fly-cutting process, the bottom surface 522 of the lower reflowable material 52 may be exposed by the bottom surface 622 of the first lower dielectric layer 62. In some embodiments, the bottom surface 522 of the lower reflowable material 52 may be recessed from the bottom surface 622 of the first lower dielectric layer 62 by about 100 nm.

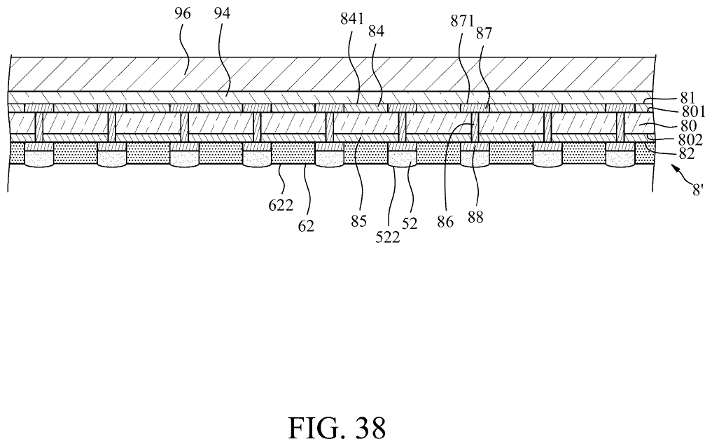

Referring to FIG. 38, the first lower dielectric layer 62 may be etched or thinned by descumming so that the lower reflowable material 52 may protrude from the bottom surface 622 of the first lower dielectric layer 62 by less than 1 μm.

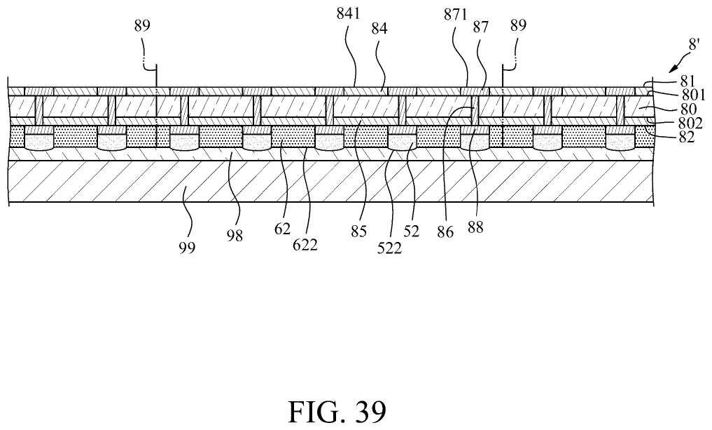

Referring to FIG. 39, the first electronic device 8′ and the first lower dielectric layer 62 may be disposed on a release layer 98 on a carrier 99. Then, the release layer 94 and the carrier 96 may be removed.

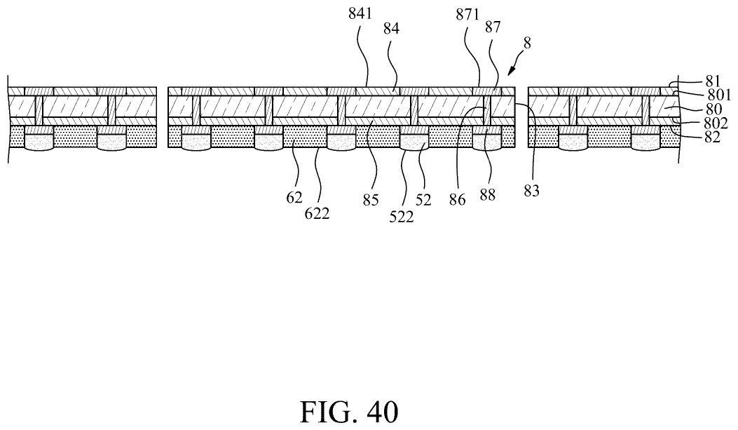

Referring to FIG. 40, the release layer 98 and the carrier 99 may be removed. Then, a singulation process may be conducted along the cutting lines 89 so as to form a plurality of first electronic devices 8.

The second electronic device 8a and the third electronic device 8b may be manufactured by the method for manufacturing the first electronic device 8.

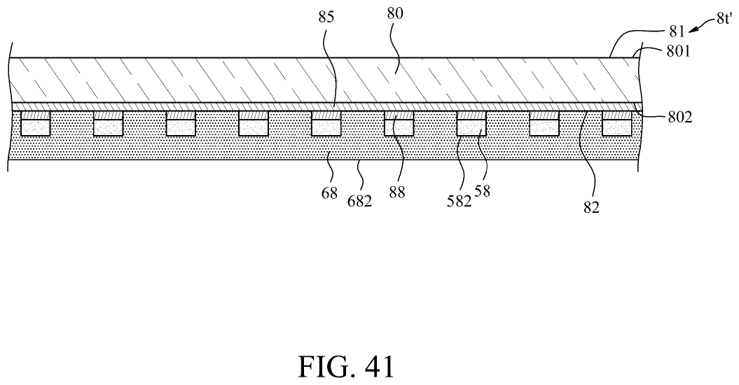

Referring to FIG. 41, a top electronic device 8t′ may be provided. The top electronic device 8t′ of FIG. 41 may be the same as the top electronic device 8t of FIG. 33. Then, a dielectric layer 68 may be formed or disposed on the bottom surface 82 of the top electronic device 8t′ to cover the third reflowable material 58 by coating. The dielectric layer 68 may include an organic material such as polyimide (PI), benzocyclobutene (BCB) or polybenzoxazoles (PBO). The bottom surface 682 (e.g., an outer surface) of the dielectric layer 68 may be lower than the bottom surface 582 of the third reflowable material 58. Then, the dielectric layer 68 may be pre-cured, for example, at a temperature of 140° C. for 30 minutes, so that the dielectric layer 68 is in a B-stage state.

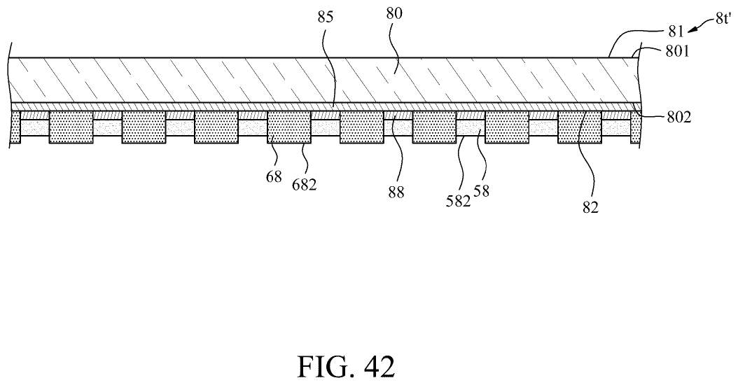

Referring to FIG. 42, a fly-cutting process may be conducted on the bottom surface 682 of the dielectric layer 68. After the fly-cutting process, the bottom surface 582 of the third reflowable material 58 may be exposed by the bottom surface 682 of the dielectric layer 68. In some embodiments, the bottom surface 582 of the third reflowable material 58 may be recessed from the bottom surface 682 of the dielectric layer 68 by about 100 nm.

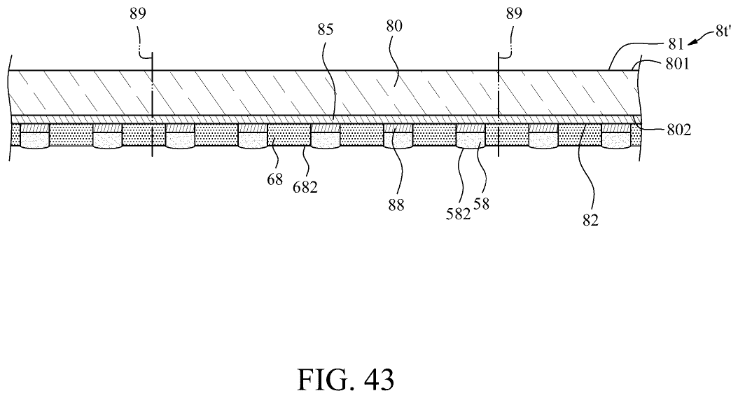

Referring to FIG. 43, the dielectric layer 68 may be etched or thinned by descumming so that the third reflowable material 58 may protrude from the bottom surface 682 of the dielectric layer 68 by less than 1 μm.

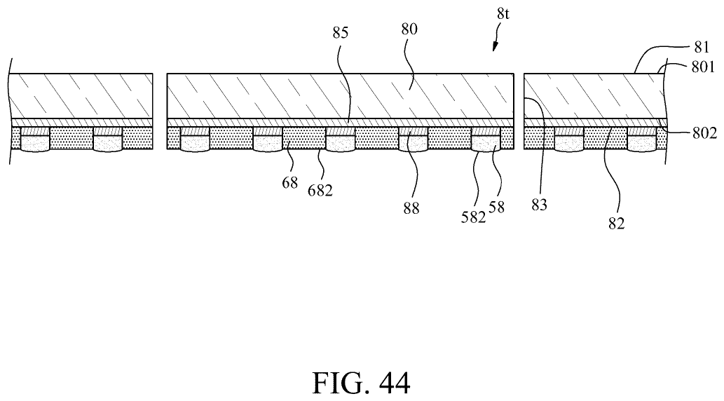

Referring to FIG. 44, a singulation process may be conducted along the cutting lines 89 so as to form a plurality of top electronic devices 8t.

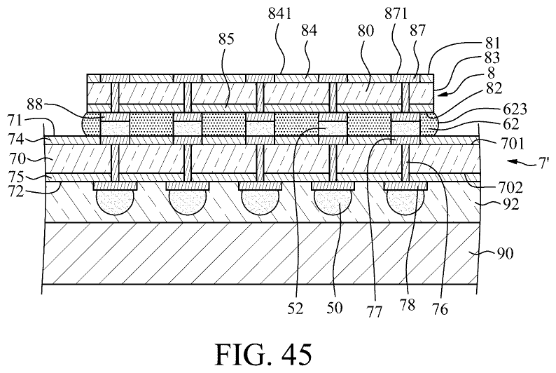

Referring to FIG. 45, the first electronic device 8 of FIG. 40 may be bonded to the bottom portion 7′ of FIG. 35. For example, the first lower dielectric layer 62 may be bonded to the upper conductive structure 74 of the bottom portion 7′ in the reducing atmosphere at a temperature of between 130° C. and 170° C. (e.g., at 150° C.) . Thus, the first lower dielectric layer 62 may become form a lower dielectric structure 62. It is noted that the lower dielectric structure 62 is still in a B-stage state. Then, a reflowing process may be performed to bond the lower reflowable material 52 to the upper connector 77 to form a lower solder structure 52 at a temperature of between 240° C. and 260° C. for 15 minutes. Then, a fully curing process may be performed to fully cure the lower dielectric structure 62 at a temperature of about 200° C. for 2 hours.

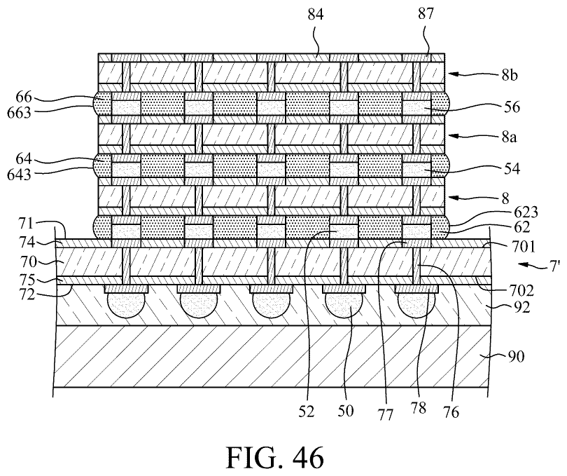

Referring to FIG. 46, the second electronic device 8a may be bonded to the first electronic device 8. The third electronic device 8b may be bonded to the second electronic device 8a.

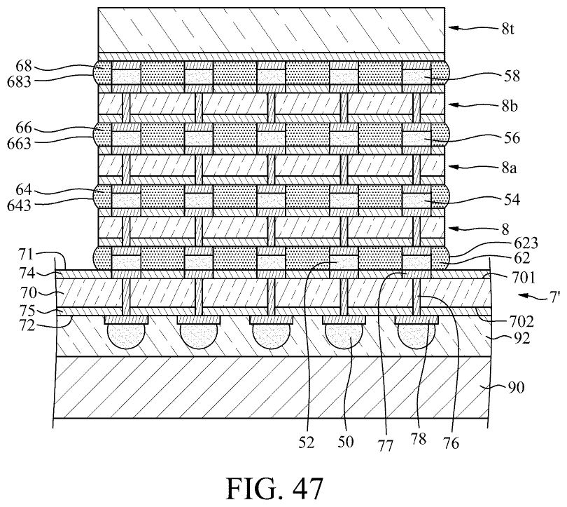

Referring to FIG. 47, the top electronic device 8t may be bonded to the third electronic device 8b.

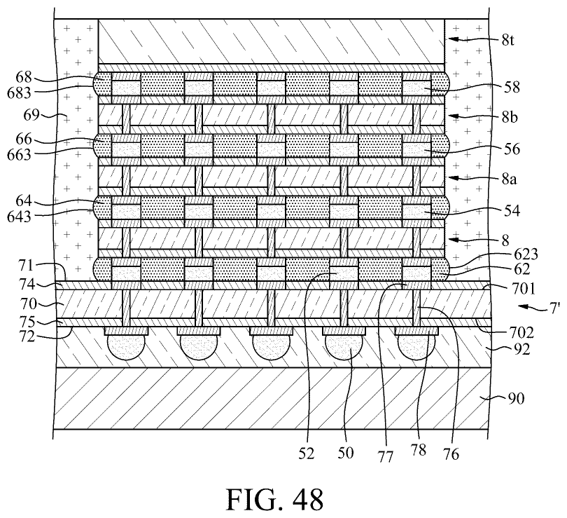

Referring to FIG. 48, an encapsulant 29 may be formed on the top surface 71 of the bottom portion 7′ to encapsulate and cover the first electronic device 8, the second electronic device 8a, the third electronic device 8b and the top electronic device 8t.

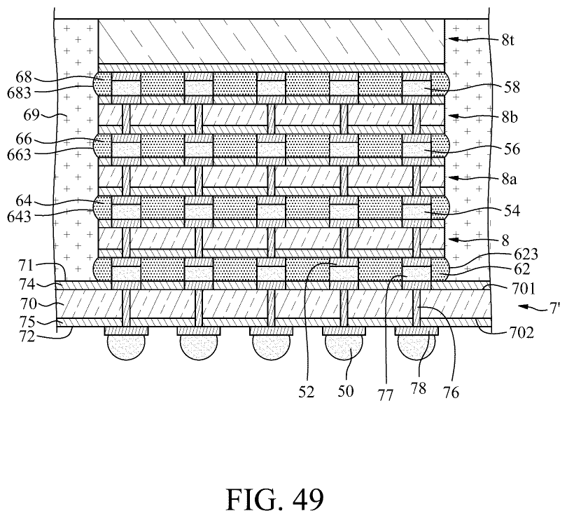

Referring to FIG. 49, the release layer 92 and the carrier 90 may be removed.

Then, a singulation process may be conducted so as to form a plurality of assembly structures 6 shown in FIG. 33.

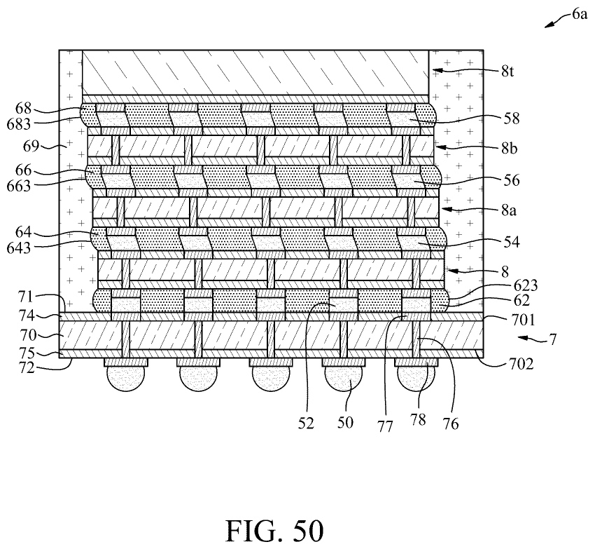

FIG. 50 illustrates a cross-sectional view of an assembly structure 6a according to some embodiments of the present disclosure. The assembly structure 6a of FIG. 50 is similar to the assembly structure 6 of FIG. 33 except that the second electronic device 8a may be misaligned with the first electronic device 8, the third electronic device 8b may be misaligned with the second electronic device 8a, and the top electronic device 8t may be misaligned with the third electronic device 8b.

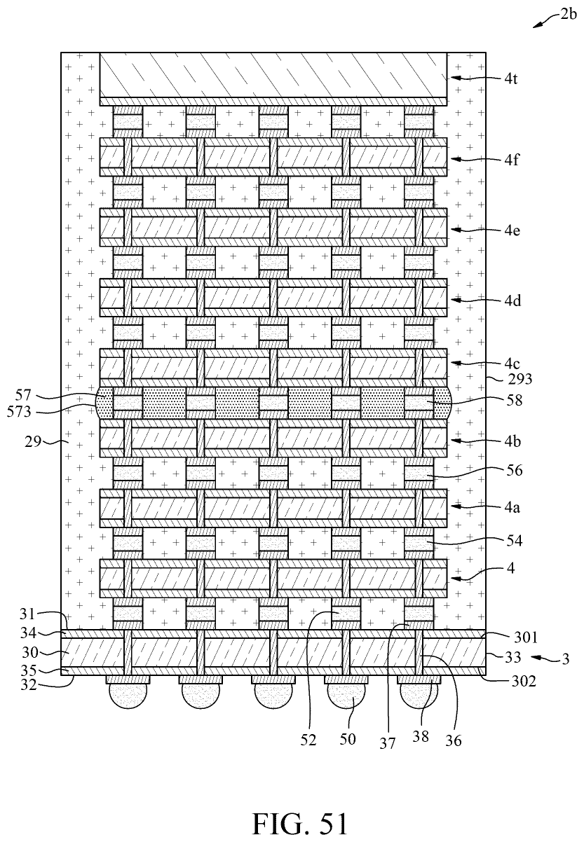

FIG. 51 illustrates a cross-sectional view of an assembly structure 2b according to some embodiments of the present disclosure. The assembly structure 2b of FIG. 51 is similar to the assembly structure 2 of FIG. 12, and the differences are described as follows. A fourth electronic device 4c may be bonded to the third electronic device 4b. A fifth electronic device 4d may be bonded to the fourth electronic device 4c. A sixth electronic device 4e may be bonded to the fifth electronic device 4d. A seventh electronic device 4f may be bonded to the sixth electronic device 4e. The top electronic device 4t may be bonded to the seventh electronic device 4f. The lower dielectric structure 51, the first dielectric structure 53 and the second dielectric structure 55 may be omitted. The third dielectric structure 57 may be disposed between the fourth electronic device 4c and the third electronic device 4b.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An assembly structure, comprising:
a first electronic device;
a second electronic device disposed over the first electronic device;
a conductive portion connecting the first electronic device and the second electronic device; and
a dielectric structure encapsulating the conductive portion, and extending beyond a lateral surface of the first electronic device and a lateral surface of the second electronic device.

2. The assembly structure of claim 1, wherein each of the first electronic device and the second electronic device is a semiconductor chip or a semiconductor die, wherein the dielectric structure includes an organic material.

3. The assembly structure of claim 1, wherein the conductive portion includes:
a first connector extending beyond a top surface of the first electronic device;
a second connector extending beyond a bottom surface of the second electronic device; and
a solder structure disposed between the first connector and the second connector.

4. The assembly structure of claim 3, wherein a lateral surface of the solder structure is a convex surface, wherein a curvature of the lateral surface of the solder structure is different from a curvature of a lateral surface of the dielectric structure.

5. The assembly structure of claim 1, wherein the conductive portion includes:
a first connector embedded in the first electronic device, and exposed by a top surface of the first electronic device;
a second connector extending beyond a bottom surface of the second electronic device; and
a solder material disposed between the first connector and the second connector.

6. The assembly structure of claim 1, wherein the first electronic device includes a first conductive structure, the first conductive structure includes an inorganic material, the second electronic device includes a second conductive structure, the second conductive structure includes an inorganic material, the dielectric structure contacts the first conductive structure and the second conductive structure.

7. The assembly structure of claim 1, further comprising:
a logic device disposed under and electrically connected to the first electronic device; and
an encapsulant encapsulating the first electronic device and the second electronic device.

8. The assembly structure of claim 7, further comprising:
a lower conductive portion connecting the first electronic device and the logic device; and
a lower dielectric structure encapsulating the lower conductive portion, and extending beyond a lateral surface of the first electronic device, wherein the lower dielectric structure includes an organic material and a portion of the lower dielectric structure is between the encapsulant and a top surface of the logic device.

9. The assembly structure of claim 8, wherein a curvature of a lateral surface of the lower dielectric structure is different from a curvature of a lateral surface of the dielectric structure.

10. A manufacturing method, comprising:
forming a first dielectric layer on a first electronic device to cover an end surface of a first reflowable material on the first electronic device, wherein the first dielectric layer includes an organic material;
removing a portion of the first dielectric layer to expose the first reflowable material;
forming a second dielectric layer on a second electronic device to cover an end surface of a second reflowable material on the second electronic device, wherein the second dielectric layer includes an organic material;
removing a portion of the second dielectric layer to expose the second reflowable material;
bonding the first dielectric layer and the second dielectric layer together to collectively form a dielectric structure; and
fusing the first reflowable material and the second reflowable material together to collectively form a solder structure.

11. The manufacturing method of claim 10, further comprising:
pre-curing the first dielectric layer, so that the first dielectric layer is in a B-stage state; and
pre-curing the second dielectric layer, so that the second dielectric layer is in a B-stage state.

12. The manufacturing method of claim 10, wherein removing the portion of the first dielectric layer includes:
removing the portion of the first dielectric layer and a portion of the first reflowable material, wherein the first reflowable material is recessed from an outer surface of the first dielectric layer.

13. The manufacturing method of claim 10, wherein removing the portion of the second dielectric layer to expose the second reflowable material includes:
removing the portion of the second dielectric layer and a portion of the second reflowable material, wherein the second reflowable material is recessed from an outer surface of the second dielectric layer; and
protruding the second reflowable material from the outer surface of the second dielectric layer.

14. The manufacturing method of claim 13, further comprising:
forming a second upper dielectric layer on a top surface of the second electronic device to cover an end surface of a second upper pad protruding from a second upper conductive structure of the second electronic device, wherein the second upper dielectric layer includes an organic material; and
exposing the second upper pad.

15. The manufacturing method of claim 10, further comprising:
fully curing the dielectric structure.

16. A manufacturing method, comprising:
providing a first electronic device including a first pad embedded in and exposed by a first conductive structure of the first electronic device, wherein the first conductive structure includes an inorganic material;
forming a second dielectric layer on a second electronic device, wherein the second dielectric layer exposes a second reflowable material, and includes an organic material;
bonding the first conductive structure and the second dielectric layer; and
bonding the first pad and the second reflowable material.

17. The manufacturing method of claim 16, further comprising:
pre-curing the second dielectric layer, so that the second dielectric layer is in a B-stage state.

18. The manufacturing method of claim 16, wherein forming the second dielectric layer on the second electronic device includes:
forming the second dielectric layer on the second electronic device to cover an end surface of the second reflowable material on the second electronic device;
removing a portion of the second dielectric layer and a portion of the second reflowable material, wherein the second reflowable material is recessed from an outer surface of the second dielectric layer; and
protruding the second reflowable material from the outer surface of the second dielectric layer.

19. The manufacturing method of claim 16, wherein bonding the first conductive structure and the second dielectric layer is performed in a reducing atmosphere at a temperature of between 130° C. and 170° C..

20. The manufacturing method of claim 16, further comprising:
fully curing the second dielectric layer.
